(19) United States
(12) Patent Application Publication
(10) Pub. No.: US 2026/0117361 A1
(43) Pub. Date: Apr. 30, 2026

(54) DEPOSITION MASK, METHOD OF MANUFACTURING THE SAME, METHOD OF MANUFACTURING DISPLAY PANEL USING THE SAME, AND ELECTRONIC DEVICE MANUFACTURED BY USING THE SAME

(71) Applicant: Samsung Display Co., LTD., Yongin-si (KR)

(72) Inventors: Jong Hoon CHOI, Yongin-si (KR); Kyong Tae YU, Yongin-si (KR)

(21) Appl. No.: 19/228,002

(22) Filed: Jun. 4, 2025

(30) Foreign Application Priority Data
Oct. 25, 2024 (KR) 10-2024-0147660

(51) Int. Cl. C23C 14/04; H10K 59/12; H10K 71/16

(52) U.S. Cl. CPC C23C 14/042; H10K 59/1201; H10K 71/166

(57) ABSTRACT

A deposition mask includes a mask frame provided with a cell opening, and a membrane disposed on the mask frame and provided with a plurality of pixel openings communicating with the cell opening. The membrane includes silicon nitride and has a first surface adjacent to the mask frame and a second surface spaced apart from the mask frame, and a silicon content of the membrane increases in a direction from the first surface toward the second surface.

This application claims priority to Korean Patent Application No. 10-2024-0147660, filed on Oct. 25, 2024, and all the benefits accruing therefrom under 35 U.S. C. § 119, the content of which in its entirety is herein incorporated by reference.

### BACKGROUND

### 1. Field

The present disclosure relates to a deposition mask, a method of manufacturing the deposition mask, a method of manufacturing a display panel using the deposition mask, and an electronic device manufactured by using the deposition mask.

### 2. Description of the Related Art

Wearable devices in which a focus is formed at a distance close to user's eyes have been developed in the form of glasses or a helmet. For example, the wearable device may be a head mounted display (HMD) device or AR glasses. The wearable device may provide an augmented reality (AR) screen or a virtual reality (VR) screen to a user.

In the case of wearable devices such as the HMD device or the AR glasses, a display specification of approximately 3000 pixels per inch (PPI) or higher is desired to allow users to use them for a long time without symptoms of dizziness. To this end, organic light emitting diode on silicon (OLEDoS) technology is emerging for use in a high-resolution small organic light emitting display device. The OLEDoS is a technology in which organic light emitting diodes (OLED) are disposed on a semiconductor substrate on which complementary metal oxide semiconductor (CMOS) elements are disposed.

In order to manufacture a display panel with a high resolution of about 3000 PPI or higher, a high-resolution deposition mask is desired. For example, the deposition mask may be manufactured by forming a membrane defining a plurality of pixel openings on a substrate such as a silicon wafer, and partially removing the substrate to form cell openings that expose the pixel openings.

### SUMMARY

In a deposition mask, the pixel openings may be formed through an anisotropic etching process, and may have a lower width adjacent to the cell openings and an upper width that is equal to or larger than the lower width. In this case, in a deposition process for forming light emitting layers of a display panel, the lower portions of the pixel openings may face a deposition source, and the upper portions of the pixel openings may be disposed adjacent to a backplane substrate. Therefore, in the deposition process, there is a problem that the loss of a deposition material may increase, and the thickness and size of the light emitting layers may become non-uniform.

Embodiments of the present disclosure provide a deposition mask having a structure in which a lower width of pixel openings is greater than an upper width of the pixel openings, a method of manufacturing the deposition mask, a method of manufacturing a display panel using the deposition mask, and an electronic device manufactured by using the deposition mask.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

In accordance with an embodiment of the present disclosure, a deposition mask includes a mask frame provided with a cell opening, and a membrane disposed on the mask frame and provided with a plurality of pixel openings communicating with the cell opening. In such an embodiment, the membrane includes silicon nitride and has a first surface adjacent to the mask frame and a second surface spaced apart from the mask frame, and a silicon content of the membrane increases in a direction from the first surface toward the second surface.

In accordance with some embodiments of the present disclosure, an average value of the silicon content of the membrane may be greater than a silicon content of stoichiometric silicon nitride.

In accordance with some embodiments of the present disclosure, an average ratio of the silicon content to a nitrogen content of the membrane may be in a range of about 0.8 to about 1.2.

In accordance with some embodiments of the present disclosure, a minimum ratio of the silicon content to a nitrogen content of the membrane may be about 0.8 or greater, and a maximum ratio of the silicon content to the nitrogen content of the membrane may be about 1.2 or less.

In accordance with some embodiments of the present disclosure, a width of each of the pixel openings may increase in a direction from the second surface toward the first surface.

In accordance with some embodiments of the present disclosure, an inner surface of the membrane defining each of the pixel openings may have an inclination angle of about 30° to about 85°.

In accordance with some embodiments of the present disclosure, the membrane may include a plurality of silicon nitride films stacked on the mask frame.

In accordance with some embodiments of the present disclosure, silicon contents of the silicon nitride films may increase in a stepwise manner in a direction from the first surface toward the second surface.

In accordance with some embodiments of the present disclosure, among the silicon nitride films, a ratio of a silicon content to a nitrogen content of a silicon nitride film defining the first surface may be about 0.8 or greater, and among the silicon nitride films, a ratio of a silicon content to a nitrogen content of a silicon nitride film defining the second surface may be about 1.2 or less.

In accordance with some embodiments of the present disclosure, a width of each of the pixel openings may increase in a stepwise manner in a direction from the second surface toward the first surface.

In accordance with another embodiment of the present disclosure, a method of manufacturing a deposition mask includes forming an inorganic film on a mask substrate, patterning the inorganic film to form a membrane with a plurality of pixel openings exposing the mask substrate, and patterning the mask substrate to form a mask frame with a cell opening communicating with the pixel openings. In such an embodiment, the inorganic film includes silicon nitride and has a first surface adjacent to the mask substrate and a second surface spaced apart from the mask substrate, and a silicon content of the inorganic film increases in a direction from the first surface toward the second surface.

In accordance with some embodiments of the present disclosure, an average value of the silicon content of the inorganic film may be greater than a silicon content of stoichiometric silicon nitride.

In accordance with some embodiments of the present disclosure, an average ratio of the silicon content to a nitrogen content of the inorganic film may be in a range of about 0.8 to about 1.2.

In accordance with some embodiments of the present disclosure, a minimum ratio of the silicon content to a nitrogen content of the inorganic film may be about 0.8 or greater, and a maximum ratio of the silicon content to the nitrogen content of the inorganic film may be about 1.2 or less.

In accordance with some embodiments of the present disclosure, the inorganic film may be formed by a chemical vapor deposition process using a first source gas containing silicon and a second source gas containing nitrogen, and a supply flow rate ratio of the first source gas to the second source gas may be increased while forming the inorganic film.

In accordance with some embodiments of the present disclosure, the pixel openings may be formed by an anisotropic etching process using a reaction gas containing fluorine, and each of the pixel openings may be formed in a way such that a width thereof increases in a direction from the second surface toward the first surface.

In accordance with some embodiments of the present disclosure, the pixel openings may be formed in a way such that an inner surface of the membrane defining each of the pixel openings has an inclination angle of about 30° to about 85 °.

In accordance with some embodiments of the present disclosure, the inorganic film may include a plurality of silicon nitride films stacked on the mask substrate, and the silicon nitride films may be formed in a way such that silicon contents thereof increase in a stepwise manner in a direction from the first surface toward the second surface.

In accordance with some embodiments of the present disclosure, the silicon nitride films may be formed by a chemical vapor deposition process using a first source gas containing silicon and a second source gas containing nitrogen, and a supply flow rate ratio of the first source gas to the second source gas may be increased in a stepwise manner while forming the silicon nitride films.

In accordance with some embodiments of the present disclosure, among the silicon nitride films, a silicon nitride film defining the first surface may be formed in a way such that a ratio of a silicon content to a nitrogen content is about 0.8 or greater, and among the silicon nitride films, a silicon nitride film defining the second surface may be formed in a way such that a ratio of a silicon content to a nitrogen content is about 1.2 or less.

In accordance with still another embodiment of the present disclosure, a method of manufacturing a display panel includes positioning a substrate on a deposition mask, and providing a light emitting material in a vapor phase through the deposition mask to form light emitting layers on the substrate. In such an embodiment, the deposition mask includes a mask frame provided with a cell opening, and a membrane disposed on the mask frame and provided with a plurality of pixel openings communicating with the cell opening. In such an embodiment, the membrane includes silicon nitride and has a first surface adjacent to the mask frame and a second surface spaced apart from the mask frame. In such an embodiment, a silicon content of the membrane increases in a direction from the first surface toward the second surface, and the light emitting material in the vapor phase is provided onto the substrate through the cell opening and the pixel openings.

In accordance with still another embodiment of the present disclosure, an electronic device includes a display panel. In such an embodiment, the display panel includes a substrate and a plurality of light emitting layers formed on the substrate by using a deposition mask. In such an embodiment, the deposition mask includes a mask frame provided with a cell opening, and a membrane disposed on the mask frame and provided with a plurality of pixel openings communicating with the cell opening. In such an embodiment, the membrane includes silicon nitride and has a first surface adjacent to the mask frame and a second surface spaced apart from the mask frame, and a silicon content of the membrane increases in a direction from the first surface toward the second surface.

According to embodiments of the present disclosure described above, the silicon content of the membrane may increase in a direction from the first surface toward the second surface, and the pixel openings may be formed by an anisotropic etching process using a reaction gas containing fluorine. In such embodiments, each of the pixel openings may be formed to have a width that increases in a direction from the second surface toward the first surface due to the silicon content of the membrane. Therefore, in the deposition process for forming the light emitting layers of the display panel, the loss of the deposition material may be reduced, and the thickness and size of the light emitting layers may be uniformly controlled.

Other features and embodiments may be apparent from the following detailed description and the drawings.

### BRIEF DESCRIPTION OF THE DRAWINGS

The above and other features of embodiments of the present disclosure will become more apparent by describing in detail embodiments thereof with reference to the attached drawings, in which:

FIG. 1 is a block diagram of an electronic device according to an embodiment of the present disclosure;

FIG. 2 is a schematic diagram of an electronic device according to various embodiments of the present disclosure;

FIG. 3 is an exploded perspective view illustrating a display device according to an embodiment of the present disclosure;

FIG. 4 is a block diagram illustrating the display device shown in FIG. 3;

FIG. 5 is an equivalent circuit diagram illustrating an example of a first sub-pixel shown in FIG. 4;

FIG. 6 is a schematic plan view illustrating an example of a display panel shown in FIG. 3;

FIG. 7 is a schematic enlarged plan view illustrating an example of a display area shown in FIG. 6;

FIG. 8 is a schematic enlarged plan view illustrating another example of the display area shown in FIG. 6;

FIG. 9 is a schematic cross-sectional view illustrating an example of the display panel taken along line I1-I1′ shown in FIG. 7;

FIG. 10 is a schematic cross-sectional view illustrating another example of the display panel taken along line I1-I1′ shown in FIG. 7;

FIG. 11 is a schematic perspective view illustrating an example of a head mounted display;

FIG. 12 is a schematic exploded perspective view illustrating the head mounted display shown in FIG. 11;

FIG. 13 is a schematic perspective view illustrating another example of the head mounted display;

FIG. 14 is a schematic diagram illustrating a deposition mask and a deposition apparatus including the mask stage according to an embodiment of the present disclosure;

FIG. 15 is a schematic bottom view illustrating the backplane substrate shown in FIG. 14;

FIG. 16 is a schematic plan view illustrating the deposition mask shown in FIG. 14;

FIG. 17 is a schematic enlarged plan view illustrating the mask cell regions shown in FIG. 16;

FIG. 18 is a schematic cross-sectional view taken along line I2-I2′ shown in FIG. 17;

FIG. 19 is a cross-sectional view illustrating a deposition mask according to an embodiment of the present disclosure;

FIGS. 20 to 23 are schematic cross-sectional views illustrating a method of manufacturing a deposition mask according to an embodiment of the present disclosure; and

FIGS. 24 to 27 are schematic cross-sectional views illustrating a method of manufacturing a deposition mask according to another embodiment of the present disclosure.

### DETAILED DESCRIPTION

The invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when an element or a layer is referred to as being “on” another element or layer, it can be directly on the other element or layer, or intervening layers may also be present. In contrast, when an element is referred to as being “directly on” another element, there are no intervening elements present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath”can, therefore, encompass both an orientation of above and below.

Features of each of various embodiments of the disclosure may be partially or entirely combined with each other and may technically variously interwork with each other, and respective embodiments may be implemented independently of each other or may be implemented together in association with each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings.

The display device according to an embodiment of the present disclosure can be applied to various electronic devices. The electronic device according to an embodiment of the present disclosure includes the display device described above, and may further include modules or devices having additional functions in addition to the display device.

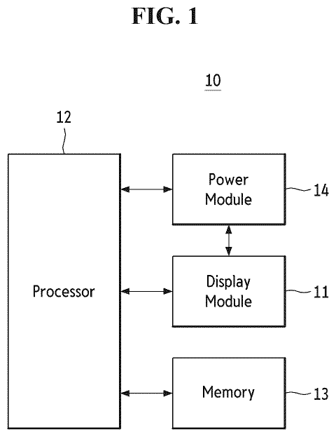

FIG. 1 is a block diagram of an electronic device according to an embodiment of the present disclosure.

Referring to FIG. 1, the electronic device 10 according to an embodiment of the present disclosure may include a display module 11, a processor 12, a memory 13, and a power module 14.

The processor 12 may include at least one selected from a central processing unit (CPU), an application processor (AP), a graphic processing unit (GPU), a communication processor (CP), an image signal processor (ISP), and a controller.

The memory 13 may store data information used for the operation of the processor 12 or the display module 11. When the processor 12 executes an application stored in the memory 13, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 10.

At least one of the components of the electronic device 10 according to an embodiment of the present disclosure may be included in the display device 20 according to embodiments of the present disclosure. In addition, some modules of the individual modules functionally included in one module may be included in the display device 20, and other modules may be provided separately from the display device 10. In an embodiment, for example, the display device 20 may include the display module 11, and the processor 12, the memory 13, and the power module 14 may be provided in the form of other devices within the electronic device 10 other than the display device 20.

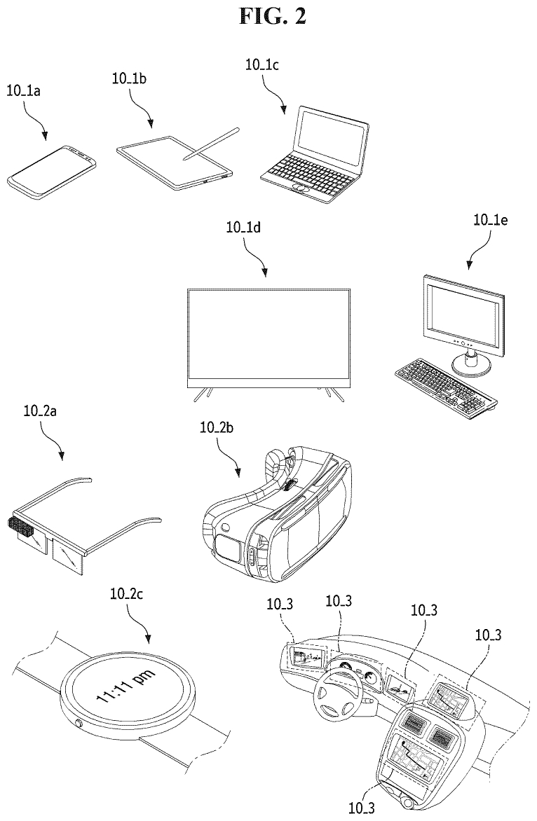

FIG. 2 is a schematic diagram of an electronic device according to various embodiments of the present disclosure.

Referring to FIG. 2, various electronic devices to which display devices 20 according to embodiments of the present disclosure are applied may include not only image display electronic devices such as a smart phone 10_1a, a tablet personal computer (PC) 10_1b, a laptop 10_1c, a television (TV) 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a Center Information Display (CID) and a room mirror display arranged on a dashboard, center fascia, and dashboard of an automobile.

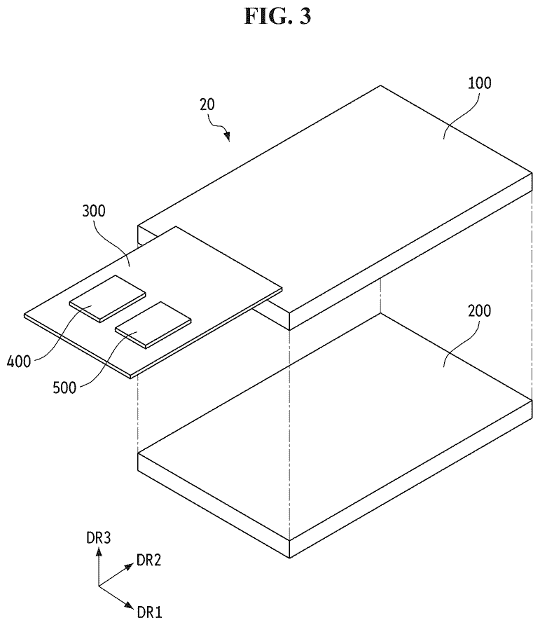

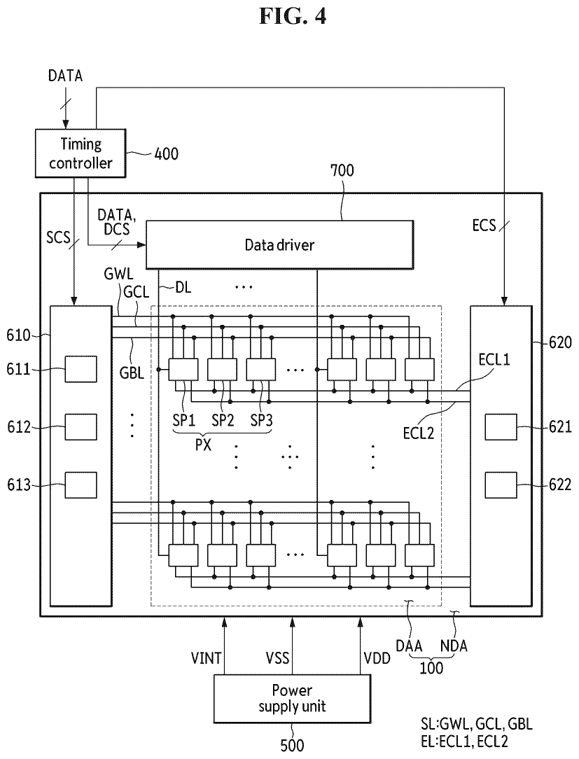

FIG. 3 is an exploded perspective view illustrating a display device according to an embodiment of the present disclosure. FIG. 4 is a block diagram illustrating the display device shown in FIG. 3.

Referring to FIGS. 3 and 4, a display device 20 according to an embodiment may be a device displaying a moving image or a still image. A display device 20 according to an embodiment may be used as the electronic device 10 or the display module 11 of the electronic device 10. For example, the display device 20 according to an embodiment may be applied to portable electronic devices 10 such as a mobile phone, a smartphone, a tablet personal computer, a mobile communication terminal, an electronic organizer, an electronic book, a portable multimedia player (PMP), a navigation system, an ultra mobile PC (UMPC), and the like. The display device 20 according to an embodiment may be applied as a display module 11 of electronic devices 10 such as a television, a laptop, a monitor, a billboard, or an Internet-of-Things (IoT) terminal, and the like. The display device 20 according to an embodiment may be applied to electronic devices 10 such as a smart watch, a watch phone, a head mounted display (HMD) for implementing virtual reality and augmented reality, and the like.

The display device 20 according to an embodiment may include a display panel 100, a heat dissipation layer 200, a circuit board 300, a timing control circuit 400, and a power supply circuit 500.

The display panel 100 may have a planar shape similar to a quadrilateral shape. In an embodiment, for example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 20 may conform to the planar shape of the display panel 100, but the present disclosure is not limited thereto.

The display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA, on which an image is displayed, and a non-display area NDA, on which no image is displayed, as shown in FIG. 4.

The plurality of pixels PX may be disposed in the display area DAA. The plurality of pixels PX may be arranged in a matrix form along the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL may include a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

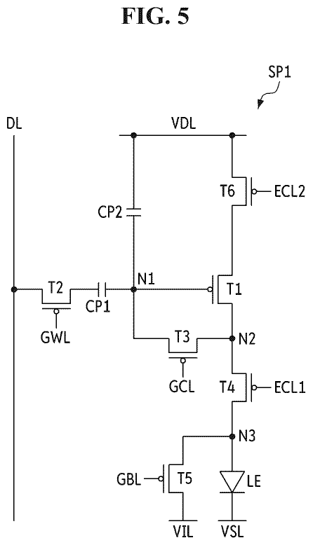

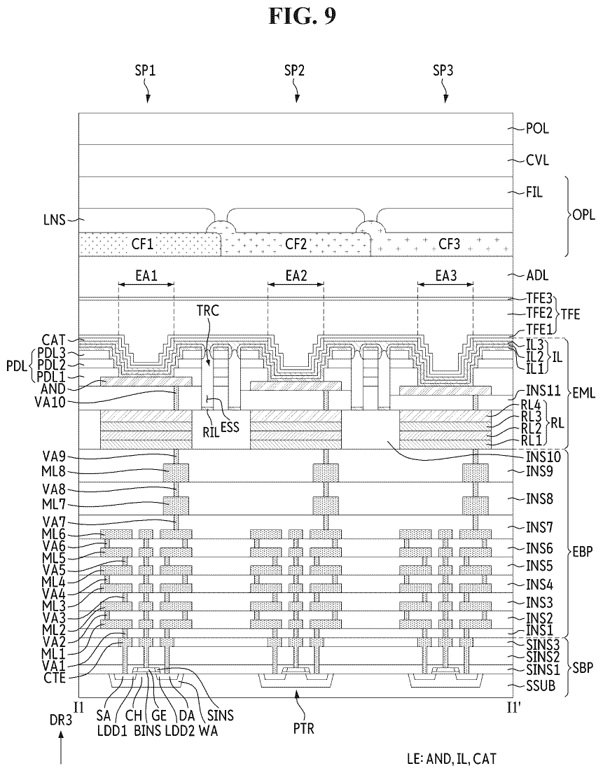

The plurality of pixels PX may include a plurality of sub-pixels SP1, SP2, and SP3. The plurality of sub-pixels SP1, SP2, and SP3 may include a plurality of pixel transistors as shown in FIG. 5, and the plurality of pixel transistors may be formed by a semiconductor process and disposed on a semiconductor substrate SSUB (see FIG. 9). In an embodiment, for example, the plurality of pixel transistors of the data driver 700 may include or be formed of complementary metal oxide semiconductor (CMOS), but the present disclosure is not limited thereto.

Each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL in response to a write scan signal of the write scan line GWL, and emit light from the light emitting element according to the data voltage.

The scan driver 610, the emission driver 620, and the data driver 700 may be disposed in the non-display area NDA.

The scan driver 610 includes a plurality of scan transistors, and the emission driver 620 includes a plurality of light emitting transistors. The plurality of scan transistors and the plurality of light emitting transistors may be formed on the semiconductor substrate SSUB (see FIG. 9) through a semiconductor process. In an embodiment, for example, the plurality of scan transistors and the plurality of light emitting transistors may include or be formed of CMOS, but the present disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals based on the scan timing control signal SCS of the timing control circuit 400 and output the write scan signals sequentially to the write scan lines GWL. The control scan signal output unit 612 may generate control scan signals based on the scan timing control signal SCS and sequentially output the control scan signals to the control scan lines GCL. The bias scan signal output unit 613 may generate bias scan signals based on the scan timing control signal SCS and output the bias scan signals sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals based on the emission timing control signal ECS and sequentially output the first emission control signals to the first emission control lines ECL1. The second emission control driver 622 may generate second emission control signals based on the emission timing control signal ECS and sequentially output the second emission control signals to the second emission control lines ECL2.

The data driver 700 may include a plurality of data transistors, and the plurality of data transistors may be formed on the semiconductor substrate SSUB (see FIG. 9) through a semiconductor process. In an embodiment, for example, the plurality of data transistors may include or be formed of CMOS, but the present disclosure is not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP 3.

The heat dissipation layer 200 may overlap the display panel 100 in a third direction DR3, which is a thickness direction of the display panel 100. The heat dissipation layer 200 may be disposed on one surface of the display panel 100, for example, on the rear surface thereof. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

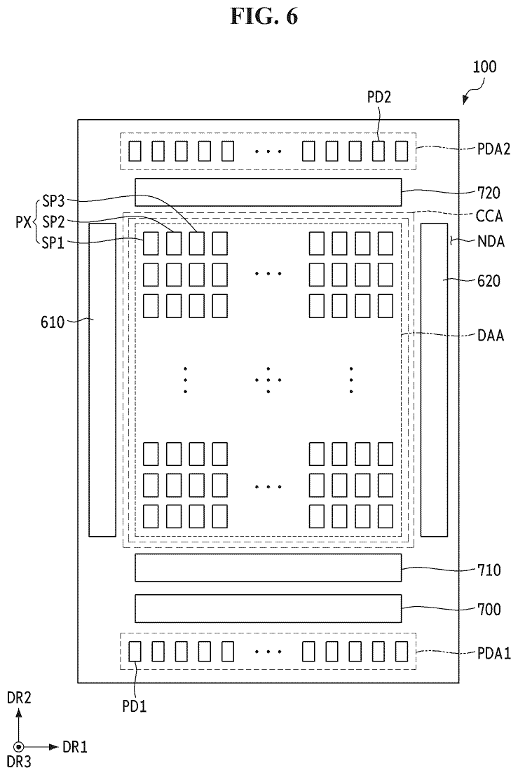

The circuit board 300 may be electrically connected to a plurality of first pads PD1 (see FIG. 6) of a first pad portion PDA1 (see FIG. 6) of the display panel 100 by using a conductive adhesive member such as an anisotropic conductive film. The circuit board 300 may be a flexible printed circuit board with a flexible material, or a flexible film. Although the circuit board 300 is illustrated in FIG. 3 as being unfolded, the circuit board 300 may be bent. In such a bend state, one end of the circuit board 300 may be disposed on the rear surface of the display panel 100 and/or the rear surface of the heat dissipation layer 200. The other end of the circuit board 300 may be connected to the plurality of first pads PD1 (see FIG. 6) of the first pad portion PDA1 (see FIG. 6) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. In an embodiment, for example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 5.

Each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 9) through a semiconductor process. In an embodiment, for example, the plurality of timing transistors and the plurality of power transistors may include or be formed of CMOS, but the present disclosure is not limited thereto. Each of the timing control circuit 400 and the power supply circuit 500 may be disposed between the data driver 700 and the first pad portion PDA1 (see FIG. 6).

FIG. 5 is an equivalent circuit diagram illustrating an example of a first sub-pixel shown in FIG. 4.

Referring to FIG. 5, an embodiment of the first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

The first sub-pixel SP1 may include a plurality of transistors (e.g., first to sixth transistors T1 to T6), a light emitting element LE, a first capacitor CP1, and a second capacitor CP2.

The light emitting element LE emits light in response to a driving current flowing through the channel of the first transistor T1. The emission amount of the light emitting element LE may be proportional to the driving current. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but the present disclosure is not limited thereto. In an embodiment, for example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor that controls a source-drain current (hereinafter referred to as “driving current”) flowing between the source electrode and the drain electrode thereof based on a voltage applied to the gate electrode thereof.

A second transistor T2 may be connected between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be connected between the first node N1 and the second node N2. The third transistor T3 is turned on by the control scan signal of the control scan line GCL to connect the first node N1 to the second node N2. Accordingly, when the first node N1 to the second node N2 are connected to each other by the third transistor T3, the gate electrode and the source electrode of the first transistor T1 are connected to each other, such that the first transistor T1 may operate like a diode.

The fourth transistor T4 may be connected between the second node N2 and a third node N3. The fourth transistor T4 is turned on by the first emission control signal of the first emission control line ECL1 to connect the second node N2 to the third node N3. Accordingly, the driving current of the first transistor T1 may be supplied to the light emitting element LE. A fifth transistor T5 may be connected between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE.

The sixth transistor T6 may be connected between the source electrode of the first transistor T1 and the second driving voltage line VDL. The sixth transistor T6 is turned on by the second emission control signal of the second emission control line ECL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is connected between the first node N1 and the drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (MOSFET). In an embodiment, for example, each of the first to sixth transistors T1 to T6 may be a P-type MOSFET, but the present disclosure is not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although FIG. 5 illustrates an embodiment where the first sub-pixel SP1 includes six transistors T1 to T6 and two capacitors C1 and C2, it should be noted that the equivalent circuit diagram of the first sub-pixel SP1 is not limited to that shown in FIG. 5. In an embodiment, for example, the number of transistors and the number of capacitors of the first sub-pixel SP1 are not limited to those shown in FIG. 5.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 5. Therefore, any repetitive detailed description of the equivalent circuit diagram of the second sub-pixel SP2 and the equivalent circuit diagram of the third sub-pixel SP3 is be omitted.

FIG. 6 is a schematic plan view illustrating an example of a display panel shown in FIG. 3.

Referring to FIG. 6, the display area DAA of the display panel 100 according to an embodiment includes the plurality of pixels PX arranged in a matrix form. The non-display area NDA of the display panel 100 according to an embodiment includes the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. In an embodiment, for example, the scan driver 610 may be disposed on one side of the display area DAA in the first direction DR1, and the emission driver 620 may be disposed on an opposing side of the display area DAA in the first direction DR1. However, the present disclosure is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. In an embodiment, for example, the first pad portion PDA1 may be disposed on one side of the display area DAA in the second direction DR2. The first pad portion PDA1 may be disposed outside the data driver 700 in the second direction DR2.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board including or made of a rigid material or a flexible printed circuit board including or made of a flexible material.

The second pad portion PDA2 may be disposed on the fourth side of the display area DAA. In an embodiment, for example, the second pad portion PDA2 may be disposed on the other side of the display area DAA in the second direction DR2. The second pad portion PDA2 may be disposed outside the second distribution circuit 720 in the second direction DR2.

The first distribution circuit 710 distributes data voltages applied through the first pad portion PDA1 to the plurality of data lines DL. In an embodiment, for example, the first distribution circuit 710 may distribute the data voltages applied through one first pad PD1 of the first pad portion PDA1 to the P data lines DL (P is a positive integer of 2 or greater), and as a result, the number of the plurality of first pads PD1 may be reduced. The first distribution circuit 710 may be disposed on the third side of the display area DAA of the display panel 100. In an embodiment, for example, the first distribution circuit 710 may be disposed on one side of the display area DAA in the second direction DR2.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. In an embodiment, for example, the second distribution circuit 720 may be disposed on the other side of the display area DAA in the second direction DR2.

A cathode connection part CCA may be a region where a second electrode CAT (see FIG. 9) of a display element layer EML (see FIG. 9) is connected to the first driving voltage line VSL of the non-display area NDA. The cathode connection part CCA may be disposed outside at least one side of the display area DAA. In an embodiment, for example, the cathode connection part CCA may be disposed outside at least on one side among the left side, the right side, the upper side, and the lower side of the display area DAA. Alternatively, the cathode connection part CCA may be disposed to surround the display area DAA as shown in FIG. 6 to minimize a deviation in the first driving voltage VSS caused by voltage drop (IR drop) or voltage rise (IR rising) of the second electrode CAT in the display area DAA.

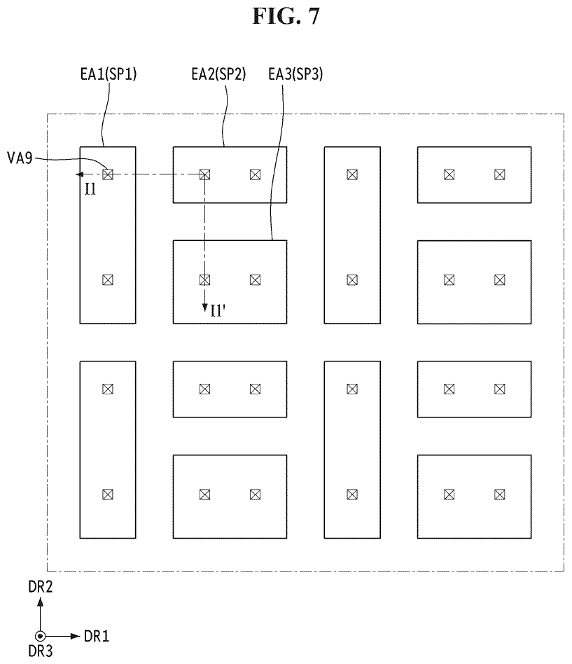

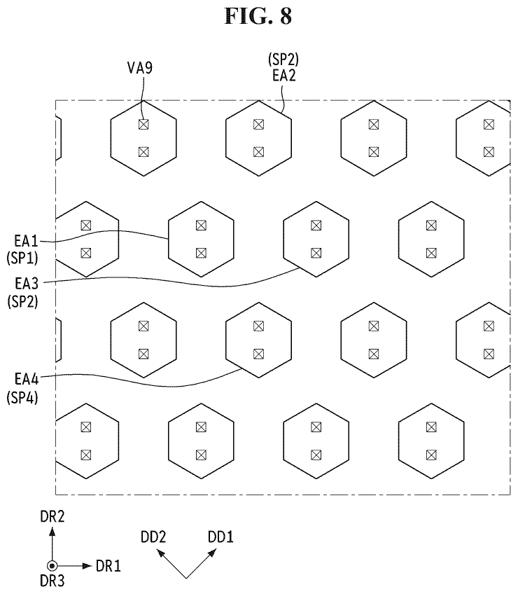

FIG. 7 is a schematic enlarged plan view illustrating an example of a display area shown in FIG. 6. FIG. 8 is a schematic enlarged plan view illustrating another example of the display area shown in FIG. 6.

Referring to FIGS. 7 and 8, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

The first emission area EA1, the second emission area EA2, and the third emission area EA3 may have, in a plan view (or when viewed in the third direction DR3), a quadrilateral or hexagonal shape as shown in FIGS. 7 and 8, but the present disclosure is not limited thereto. The first emission area EA1, the second emission area EA2, and the third emission area EA3 may have a polygonal shape other than a quadrangle or hexagon, a circular shape, an elliptical shape, or an atypical shape in plan view.

In an embodiment, as shown in FIG. 7, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

Alternatively, as shown in FIG. 8, the emission areas EA1, EA2, EA3, and EA4 may have a hexagonal shape in plan view. In such an embodiment, the first emission area EA1 and the third emission area EA3 may be adjacent in the first direction DR1, and the second emission area EA2 and the fourth emission area EA4 may be adjacent in the second direction DR2. Additionally, the first emission area EA1 and the second emission area EA2 may be adjacent in a first diagonal direction DD1, and the second emission area EA2 and the third emission area EA3 may be adjacent in a second diagonal direction DD2. Additionally, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2, and may refer to a direction inclined by about 45 degrees with respect to the first direction DR1 and the second direction DR2, and the second diagonal direction DD2 may be a direction perpendicular to the first diagonal direction DD1.

The first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. In an embodiment, for example, the blue wavelength band may be a wavelength band of light whose main peak wavelength is in a range of about 370 nanometers (nm) to about 460 nm, the green wavelength band may be a wavelength band of light whose main peak wavelength is in a range of about 480 nm to about 560 nm, and the red wavelength band may be a wavelength band of light whose main peak wavelength is in a range of about 600 nm to about 750 nm.

In embodiments, as shown in FIG. 7, each of the plurality of pixels PX may include three emission areas EA1, EA2, and EA3, or may include four emission areas EA1, EA2, EA3, and EA4 as shown in FIG. 8. In such embodiments, the fourth emission area EA4 may emit the same second light as the second emission area EA2, but the present disclosure is not limited thereto.

The emission areas of the plurality of pixels PX may be arranged in a stripe structure in which the emission areas are arranged in the first direction DR1, a PenTile® structure in which the emission areas EA1, EA2, EA3, and EA4 are arranged in a rhombic shape as shown in FIG. 8, or a hexagonal structure in which the emission areas are arranged in a hexagonal shape.

FIG. 9 is a schematic cross-sectional view illustrating an example of the display panel taken along line I1-I1′ shown in FIG. 7.

Referring to FIG. 9, an embodiment of the display panel 100 includes a semiconductor backplane SBP, a light emitting element backplane EBP, the display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may correspond to the first to sixth transistors T1 to T6 described with reference to FIG. 5.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the first type impurity. In an embodiment, for example, the first type impurity may be a p-type impurity, and the second type impurity may be an n-type impurity. Alternatively, the first type impurity may be an n-type impurity, and the second type impurity may be a p-type impurity.

Each of the plurality of well regions WA includes a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be disposed on one side of the gate electrode GE, and the drain region DA may be disposed on an opposing side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, thereby increasing the length of the channel region CH of each of the pixel transistors PTR.

A first semiconductor insulating film SINS1 may be disposed on the semiconductor substrate SSUB. A second semiconductor insulating film SINS2 may be disposed on the first semiconductor insulating film SINS1.

The plurality of contact terminals CTE may be disposed on the second semiconductor insulating film SINS2. Each of the plurality of contact terminals CTE may be connected to at least one selected from the gate electrode GE, the source region SA, and the drain region DA of each of the pixel transistors PTR through a hole penetrating the first semiconductor insulating film SINS1 and the second semiconductor insulating film SINS2. The plurality of contact terminals CTE may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy thereof.

A third semiconductor insulating film SINS3 may be disposed on a side surface of each of the plurality of contact terminals CTE. The top surface of each of the plurality of contact terminals CTE may be exposed without being covered by the third semiconductor insulating film SINS3.

In an embodiment, each of the first semiconductor insulating film SINS1, the second semiconductor insulating film SINS2, and the third semiconductor insulating film SINS3 may include or be formed of silicon carbonitride (SiCN) or a silicon oxide (SiOx)-based inorganic film, but the present disclosure is not limited thereto.

In an embodiment, the semiconductor substrate SSUB may be replaced with a glass substrate or a polymer resin substrate such as polyimide. In such an embodiment, thin film transistors may be disposed on the glass substrate or the polymer resin substrate. The glass substrate may be a rigid substrate that does not bend, and the polymer resin substrate may be a flexible substrate that can be bent or curved.

The light emitting element backplane EBP includes a plurality of conductive layers ML1 to ML8, a plurality of vias VA1 to VA9, and a plurality of interlayer insulating films INS1 to INS9.

The first to ninth interlayer insulating films INS1 to INS9 serve to insulate the first to eighth conductive layers ML1 to ML8 from each other. The first to eighth conductive layers ML1 to ML8 serve to connect the plurality of contact terminals CTE exposed from the semiconductor backplane SBP to thereby implement the circuit of the first sub-pixel SP1 shown in FIG. 5.

In an embodiment, for example, the first to sixth transistors T1 to T6 are merely formed in the semiconductor backplane SBP, and the connection of the first to sixth transistors T1 to T6 and the first and second capacitors C1 and C2 is accomplished through the first to eighth conductive layers ML1 to ML8. In addition, the connection between the drain region corresponding to the drain electrode of the fourth transistor T4, the source region corresponding to the source electrode of the fifth transistor T5, and a first electrode AND of the light emitting element LE is also accomplished through the first to eighth conductive layers ML1 to ML8.

The first to eighth conductive layers ML1 to ML8 and the first to eighth vias VA1 to VA8 may include or be formed of substantially a same material as each other. In an embodiment, the first to eighth conductive layers ML1 to ML8 and the first to eighth vias VA1 to VA8 may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy thereof. The first to eighth vias interlayer insulating films INS1 to INS8 may include or be made of substantially a same material. In an embodiment, first to eighth interlayer insulating films INS1 to INS8 may include or be formed of a silicon oxide (SiOx)-based inorganic layer, but the present disclosure is not limited thereto.

A ninth interlayer insulating film INS9 may be disposed on the eighth interlayer insulating film INS8 and the eighth conductive layer ML8. The ninth interlayer insulating film INS9 may include or be formed of a silicon oxide (SiOx)-based inorganic film, but the present disclosure is not limited thereto.

Each of the ninth vias VA9 may penetrate (or be disposed through) the ninth interlayer insulating film INS9 and be connected to the exposed portion of the eighth conductive layer ML8. The ninth vias VA9 may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy thereof.

The display element layer EML may be disposed on the light emitting element backplane EBP. The display element layer EML may include the tenth and eleventh interlayer insulating films INS10 and INS11, reflective electrodes RL, the first electrodes AND, a light emitting stack IL, the second electrode CAT, a pixel defining film PDL, and a plurality of trenches TRC.

The reflective electrodes RL may be disposed on the ninth interlayer insulating film INS9. Each of the reflective electrodes RL may include at least one reflective electrode RL1, RL2, RL3, and RL4. In an embodiment, for example, each of the reflective electrodes RL may include the first to fourth reflective electrodes RL1, RL2, RL3, and RL4 as shown in FIG. 9.

The first reflective electrodes RL1 may be disposed on the ninth interlayer insulating film INS9, and may be connected to the ninth via VA9. Each of the second reflective electrodes RL2 may be disposed on the first reflective electrode RL1 corresponding thereto. Each of the third reflective electrodes RL3 may be disposed on the second reflective electrode RL2 corresponding thereto. Each of the fourth reflective electrodes RL4 may be disposed on the third reflective electrode RL3 corresponding thereto.

Since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy thereof. In an embodiment, for example, the first reflective electrodes RL1 may include titanium nitride (TiN), the second reflective electrodes RL2 may include aluminum (Al), the third reflective electrodes RL3 may include titanium nitride (TiN), and the fourth reflective electrodes RL4 may include titanium (Ti).

The tenth interlayer insulating film INS10 may be disposed on the ninth interlayer insulating film INS9. The tenth interlayer insulating film INS10 may be disposed between the reflective electrodes RL adjacent to each other. The tenth interlayer insulating film INS10 may be a film for flattening a stepped portion caused by the reflective electrodes RL. The eleventh interlayer insulating film INS11 may be disposed on the tenth interlayer insulating film INS10 and the reflective electrodes RL.

The tenth interlayer insulating film INS10 and the eleventh interlayer insulating film INS11 may include or be formed of a silicon oxide (SiOx)-based inorganic film, but the present disclosure is not limited thereto.

The eleventh interlayer insulating film INS11 may be an optical auxiliary layer for adjusting the resonance distance of light emitted from the light emitting stack IL in at least one selected from the first sub-pixel SP1, the second sub-pixel SP2, or the third sub-pixel SP3. The thickness of the eleventh interlayer insulating film INS11 may be different in the first sub-pixel SP1, the second sub-pixel SP2, and the third sub-pixel SP3. That is, in order to adjust a distance from the reflective electrode RL to the second electrode CAT according to a main wavelength of light emitted from each of the first sub-pixel SP1, the second sub-pixel SP2, and the third sub-pixel SP3, the thickness of the eleventh interlayer insulating film INS11 may be set for each of the first sub-pixel SP1, the second sub-pixel SP2, and the third sub-pixel SP3.

In an embodiment, for example, as shown in FIG. 9, the thickness of the eleventh interlayer insulating film INS11 in the first sub-pixel SP1 may be greater than the thickness of the eleventh interlayer insulating film INS11 in the second sub-pixel SP2, and the thickness of the eleventh interlayer insulating film INS11 in the second sub-pixel SP2 may be greater than the thickness of the eleventh interlayer insulating film INS11 in the third sub-pixel SP3. In such an embodiment, the distance between the first electrode AND and the reflective electrode RL in the first sub-pixel SP1 is greater than the distance between the first electrode AND and the reflective electrode RL in the second sub-pixel SP2. In addition, the distance between the first electrode AND and the reflective electrode RL in the second sub-pixel SP2 is greater than the distance between the first electrode AND and the reflective electrode RL in the third sub-pixel SP3.

Each of the tenth vias VA10 may penetrate the eleventh interlayer insulating film INS11 and be connected to the exposed fourth reflective electrode RL4. The tenth vias VA10 may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy thereof. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light emitting elements LE may be disposed on the eleventh interlayer insulating film INS11 and connected to the tenth via VA10. The first electrode AND of each of the light emitting elements LE may be connected to the drain region DA or source region SA of the pixel transistor PTR through the tenth via VA10, the reflective electrode RL, the first to ninth vias VA1 to VA9, the first to eighth metal layers ML1 to ML8, and the contact terminal CTE. The first electrode AND of each of the light emitting elements LE may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy thereof. In an embodiment, for example, the first electrode AND of each of the light emitting elements LE may be titanium nitride (TiN).

The pixel defining film PDL may be disposed on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light emitting element LE including the first electrode AND, the light emitting stack IL, and the second electrode CAT is disposed.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may include or be formed of a silicon oxide (SiOx)-based inorganic film. Alternatively, the first pixel defining film PDL1 and the third pixel defining film PDL3 may include or be formed of a silicon nitride (SiNx)-based inorganic film, whereas the second pixel defining film PDL2 may include or be formed of a silicon oxide (SiOx)-based inorganic film. The first pixel defining film PDL1, the second pixel defining film PDL2, and the third pixel defining film PDL3 may each have a thickness of about 500 angstrom (Å).

In order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. Step coverage refers to the ratio of the degree of thin film coated on an inclined portion to the degree of thin film coated on a flat portion. The lower the step coverage, the more likely it is that the thin film will be cut off at inclined portions.

Each of the plurality of trenches TRC may penetrate (or be disposed through) the first pixel defining film PDL1, the second pixel defining film PDL2, and the third pixel defining film PDL3. The eleventh interlayer insulating film INS11 may be partially recessed at each of the plurality of trenches TRC.

At least one trench TRC may be disposed between the neighboring sub-pixels SP1, SP2, and SP3. Although FIG. 9 illustrates that two trenches TRC are disposed between the neighboring sub-pixels SP1, SP2, and SP3, the present disclosure is not limited thereto.

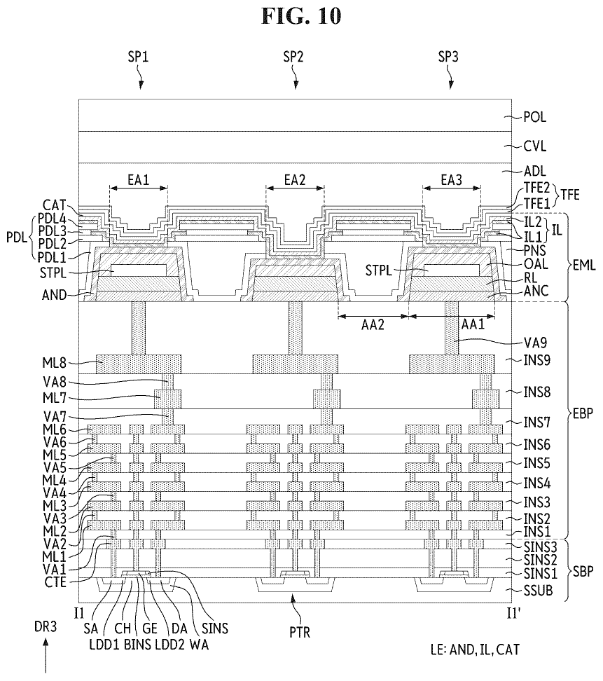

The light emitting stack IL may include a plurality of stack layers IL1, IL2, and IL3. FIG. 9 illustrates an embodiment where the light emitting stack IL has a three-tandem structure including a first stack layer IL1, a second stack layer IL2, and a third stack layer IL3, but the present disclosure is not limited thereto. In another embodiment, for example, the light emitting stack IL may have a two-tandem structure including two stack layers as shown in FIG. 10.

In an embodiment having the three-tandem structure, the light emitting stack IL may have a tandem structure including a plurality of intermediate layers IL1, IL2, and IL3 that emit different lights. In an embodiment, for example, the light emitting stack IL may include the first stack layer IL1 that emits first light, the second stack layer IL2 that emits second light, and the third stack layer IL3 that emits third light. The first stack layer IL1, the second stack layer IL2, and the third stack layer IL3 may be sequentially stacked.

The first stack layer IL1 may have a structure in which a first hole transport layer, a first light emitting layer that emits the first light, and a first electron transport layer are sequentially stacked. The second stack layer IL2 may have a structure in which a second hole transport layer, a second light emitting layer that emits the second light, and a second electron transport layer are sequentially stacked. The third stack layer IL3 may have a structure in which a third hole transport layer, a third light emitting layer that emits the third light, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and a residual film RIL disposed on the bottom surface of each trench TRC may be the same material as the first stack layer IL1. Due to the trench TRC, the first stack layer IL1 may be cut off between the neighboring sub-pixels SP1, SP2, and SP3. The second stack layer IL2 may be disposed on the first stack layer IL1. Due to the trench TRC, the second stack layer IL2 may be cut off between the neighboring sub-pixels SP1, SP2, and SP3. A cavity ESS or an empty space may be defined or formed between the residual film IL and the second stack layer IL2 in the trench TRC. The third stack layer IL3 may be disposed on the second stack layer IL2. The third stack layer IL3 is not cut off by the trench TRC and may be disposed to cover the second stack layer IL2 in each of the trenches TRC.

In an embodiment having the three-tandem structure, each of the plurality of trenches TRC may be a structure for cutting off the first to third hole transport layers, the first charge generation layer, and the second charge generation layer of the first to third stack layers IL1, IL2, and IL3 of the display element layer EML between the neighboring sub-pixels SP1, SP2, and SP3. In an embodiment having the two-tandem structure, each of the plurality of trenches TRC may be a structure for cutting off the charge generation layer and the lower stack layer disposed between the lower stack layer and the upper stack layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the charge generation layers and the hole transport layers of the light emitting stack IL of the display element layer EML between the neighboring sub-pixels SP1, SP2, and SP3, a different structure may be present instead of the trench TRC. In an embodiment, for example, instead of the trench TRC, a reverse tapered partition wall may be disposed on the pixel defining film PDL.

In addition, FIG. 9 illustrates an embodiment where the light emitting stack IL that emits light is disposed in the first emission area EA1, the second emission area EA2, and the third emission area EA3, but the present disclosure is not limited thereto. In another embodiment, for example, instead of the light emitting stack IL, the first light emitting layer may be disposed in the first emission area EA1, and may be omitted from the second emission area EA2 and the third emission area EA3. Furthermore, the second light emitting layer may be disposed in the second emission area EA2 and may be omitted from the first emission area EA1 and the third emission area EA3. Furthermore, the third light emitting layer may be disposed in the third emission area EA3 and may be omitted from the first emission area EA1 and the second emission area EA2. In such an embodiment, first to third color filters CF1, CF2, and CF3 of the optical layer OPL may be omitted.

The second electrode CAT may be disposed on the light emitting stack IL. That is, the second electrode CAT may be disposed on the third stack layer IL3. The second electrode CAT may include or be formed of a transparent conductive material (TCO) such as ITO or IZO that can transmit light or a semi-transmissive conductive material such as magnesium (Mg), silver (Ag), or an alloy of Mg and Ag. In an embodiment where the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE3 to prevent oxygen or moisture from permeating into the display element layer EML. The first encapsulation inorganic film TFE1 may be disposed on the second electrode CAT, and the second encapsulation inorganic film TFE3 may be disposed above the first encapsulation inorganic film TFE1. The first encapsulation inorganic film TFE1 and the second encapsulation inorganic film TFE3 may include or be formed of multiple layers in which one or more inorganic films of silicon nitride (SiNx), silicon oxynitride (SiON), silicon oxide (SiOx), titanium oxide (TiOx), and aluminum oxide (AlOx) layers are alternately stacked.

In addition, the encapsulation layer TFE may include at least one organic film TFE2 to protect the display element layer EML from foreign substances such as dust. The encapsulating organic film TFE2 may be disposed between the first encapsulating inorganic film TFE1 and the second encapsulating inorganic film TFE3. The encapsulation organic film TFE2 may be a monomer. Alternatively, the encapsulation organic film TFE2 may be an organic film such as acryl resin, epoxy resin, phenolic resin, polyamide resin, polyimide resin or the like.

An adhesive layer ADL may be a layer for bonding the encapsulation layer TFE to the optical layer OPL. The adhesive layer ADL may be a double-sided adhesive member. In addition, the adhesive layer ADL may be a transparent adhesive member such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the adhesive layer ADL.

The first color filter CF1 may overlap the first emission area EA1 of the first sub-pixel SP1. The first color filter CF1 may transmit light of the first color, i.e., light of a blue wavelength band. The blue wavelength band may be about 370 nm to about 460 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, i.e., light of a green wavelength band. The green wavelength band may be about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, i.e., light of a red wavelength band. The red wavelength band may be about 600 nm to about 750 nm. Thus, the third color filter CF3 may transmit light of the third color among light emitted from the third emission area EA3.

The plurality of lenses LNS may be disposed on the first color filter CF1, the second color filter CF2, and the third color filter CF3, respectively. Each of the plurality of lenses LNS may be a structure for increasing the proportion of light directed to the front of the display device 10. Each of the plurality of lenses LNS may have a cross-sectional shape that is convex in an upward direction.

The filling layer FIL may be disposed on the plurality of lenses LNS. The filling layer FIL may have a predetermined refractive index such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be disposed on the filling layer FIL. The cover layer CVL may be a glass substrate or a polymer resin layer. In an embodiment where the cover layer CVL is a glass substrate, the cover layer CVL may be attached onto the filling layer FIL. In this case, the filling layer FIL may serve to bond the cover layer CVL. In an embodiment where the cover layer CVL is a glass substrate, the cover layer CVL may serve as an encapsulation substrate. In an embodiment where the cover layer CVL is a polymer resin layer, the cover layer CVL may be directly applied onto the filling layer FIL.

The polarizing plate may be disposed on one surface of the cover layer CVL. The polarizing plate may be a structure for substantially reducing or effectively preventing visibility degradation caused by reflection of external light. The polarizing plate may include a linear polarizing plate and a phase retardation film. For example, the phase retardation film may be a λ/4 plate (quarter-wave plate), but the present disclosure is not limited thereto. However, when visibility degradation caused by reflection of external light is sufficiently overcome by the first to third color filters CF1, CF2, and CF3, the polarizing plate may be omitted.

FIG. 10 is a schematic cross-sectional view illustrating another example of the display panel taken along line I1-I1′ shown in FIG. 7.

The embodiment of FIG. 10 is substantially the same as the embodiment of FIG. 9 except that the first electrode AND of each of the light emitting elements LE is in contact with and electrically connected to the side surface of a connection electrode ANC connected to the eighth conductive layer ML8, the trench TRC is omitted, and the third pixel defining film PDL3 and a fourth pixel defining film PDL4 have an eave-shaped or mushroom-shaped cross-sectional structure. The same or like elements shown in FIG. 10 are labeled with the same reference characters as used above to describe the embodiment of FIG. 9, and any repetitive detailed description thereof will hereinafter be omitted or simplified.

Referring to FIG. 10, the plurality of connection electrodes ANC may be respectively disposed on first portions AA1 of the ninth interlayer insulating film INS9. Each of the plurality of connection electrodes ANC may be disposed on the first portion AA1 of the ninth interlayer insulating film INS9 corresponding thereto. A plurality of connection electrodes ANC may include or be formed of at least one selected from copper (Cu), aluminum (Al), tungsten (W), molybdenum (Mo), chromium (Cr), gold (Au), titanium (Ti), nickel (Ni), and neodymium (Nd), an alloy thereof, or a transparent conductive oxide. In an embodiment, for example, each of the plurality of connection electrodes ANC may include titanium (Ti), titanium nitride (TiN), indium tin oxide (ITO), or indium zinc oxide (IZO), but the present disclosure is limited thereto.

A plurality of reflective electrodes RL may be respectively disposed on the plurality of connection electrodes ANC. Each of the plurality of reflective electrodes RL may be disposed on the connection electrode ANC corresponding thereto. The plurality of reflective electrodes RL may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy thereof. In an embodiment, for example, each of the plurality of reflective electrodes RL may include aluminum (Al) having high reflectivity.

A plurality of optical auxiliary films OAL may be respectively disposed on the plurality of reflective electrodes RL. Each of the plurality of optical auxiliary films OAL may be disposed on the reflective electrode RL corresponding thereto. The plurality of optical auxiliary films OAL may include or be formed of a silicon oxide (SiOx)-based inorganic film, but the present disclosure is not limited thereto.

In each of the first emission area EA1 and the third emission area EA3, a step layer STPL may be disposed on the reflective electrode RL, and the optical auxiliary film OAL may be disposed on the step layer STPL. In the second emission area EA2, only the optical auxiliary film OAL may be disposed on the reflective electrode RL. The thicknesses of the optical auxiliary film OAL may be substantially the same in the first emission area EA1, the second emission area EA2, and the third emission area EA3.

Due to the step layer STPL, the distance between the reflective electrode RL and the first electrode AND in the first emission area EA1 and the third emission area EA3 may be greater than the distance between the reflective electrode RL and the first electrode AND in the second emission area EA2. The thickness of the step layer STPL and the thickness of the optical auxiliary layer OAL may be set or determined in consideration of the wavelength and resonance distance of light emitted from the first stack layer IL1 of the light emitting stack IL, and the wavelength and resonance distance of light emitted from the second stack layer IL2 thereof.

Each of the light emitting elements LE may include the first electrode AND, a light emitting stack IL, and a second electrode CAT.

The first electrode AND of each of the light emitting elements LE may be disposed on the optical auxiliary film OAL corresponding thereto. Since the connection electrode ANC, the reflective electrode RL, and the optical auxiliary layer OAL are sequentially stacked, the first electrode AND of each of the light emitting elements LE may be disposed on the top surface and the side surface of the optical auxiliary layer OAL, the side surface of the reflective electrode RL, and the side surface of the connection electrode ANC. Accordingly, the first electrode AND of each of the light emitting elements LE may be in contact with and electrically connected to the side surface of the reflective electrode RL and the side surface of the connection electrode ANC. Therefore, compared to when the first electrode AND of each of the light emitting elements LE is connected to the reflective electrode RL exposed through a through hole penetrating the optical auxiliary film OAL, the number of mask processes may be reduced, thereby lowering manufacturing cost and increasing manufacturing efficiency.

The first electrode AND of each of the light emitting elements LE may be connected to the drain region DA or the source region SA of the pixel transistor PTR through the connection electrode ANC, the first to ninth vias VA1 to VA9, the first to eighth conductive layers ML1 to ML8, and the contact terminal CTE.

The ninth interlayer insulating film INS9 may include the first portion AA1 that overlaps the connection electrode ANC in the third direction DR3 and a second portion AA2 that does not overlap the connection electrode ANC in the third direction DR3. The thickness of the first portion AA1 and the thickness of the second portion AA2 of the ninth interlayer insulating film INS9 may be substantially the same.

Alternatively, the thickness of the first portion AA1 of the ninth interlayer insulating film INS9 may be greater than the thickness of the second portion AA2 thereof. In this case, the side surface of the first portion AA1 of the ninth interlayer insulating film INS9 may be exposed, and the first electrode AND of each of the light emitting elements LE may be disposed on the exposed side surface of the first portion AA1 of the ninth interlayer insulating film INS9.

The first electrode AND of each of the light emitting elements LE may include or be formed of at least one selected from copper (Cu), aluminum (Al), tungsten (W), molybdenum (Mo), chromium (Cr), gold (Au), titanium (Ti), nickel (Ni), and neodymium (Nd), an alloy thereof, or a transparent conductive oxide. In an embodiment, for example, the first electrode AND of each of the light emitting elements LE may include titanium (Ti), titanium nitride (TiN), indium tin oxide (ITO), or indium zinc oxide (IZO), but the present disclosure is limited thereto.

The pixel defining film PDL may be disposed on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3.

The pixel defining film PDL may include first to fourth pixel defining films PDL1, PDL2, PDL3, and PDL4.

The first pixel defining film PDL1 may be disposed on the first electrode AND of each of the light emitting elements LE. In an embodiment, the first pixel defining film PDL1 may cover a part of the top surface of the first electrode AND disposed on the optical auxiliary film OAL. Further, the first pixel defining film PDL1 may cover the first electrode AND disposed on the side surface of the connection electrode ANC, the side surface of the reflective electrode RL, and the side surface of the optical auxiliary film OAL. The first pixel defining film PDL1 may be disposed on the top surface of the second portion AA2 of the ninth interlayer insulating film INS9.

A planarization film PNS is a film for flattening the stepped portion caused by the connection electrode ANC, the reflective electrode RL, and the optical auxiliary film OAL.

The planarization film PNS may be disposed on the first pixel defining film PDL1 covering the first electrode AND disposed on the side surface of the connection electrode ANC, the side surface of the reflective electrode RL, and the side surface of the optical auxiliary film OAL. The planarization film PNS may be disposed on the first pixel defining film PDL1 disposed on the second portion AA2 of the ninth interlayer insulating film INS9.

The planarization film PNS may be disposed between the connection electrodes ANC adjacent in the first direction DR1 or the second direction DR2. The planarization film PNS may be disposed between the reflective electrodes RL adjacent in the first direction DR1 or the second direction DR2. The planarization film PNS may be disposed between the optical auxiliary films OAL adjacent in the first direction DR1 or the second direction DR2.

In an embodiment, the step layer STPL is not present in the second emission area EA2, whereas the step layer STPL is present in each of the first emission area EA1 and the third emission area EA3. Accordingly, the heights of the connection electrode ANC, the reflective electrode RL, and the optical auxiliary film OAL in the second emission area EA2 may be less than the heights of the connection electrode ANC, the reflective electrode RL, the step layer STPL, and the optical auxiliary film OAL in the first emission area EA1 and the third emission area EA3. Therefore, the planarization film PNS may cover the top surface of the first pixel defining film PDL1 disposed on the top surface of the first electrode AND disposed in the second emission area EA2.

In such an embodiment, the top surface of the planarization film PNS may be flatly connected to the top surface of the first pixel defining film PDL1 disposed on the top surface of the first electrode AND disposed in the first emission area EA1 and the third emission area EA3. That is, the top surface of the planarization film PNS may be on a same plane as the top surface of the first pixel defining film PDL1, and the planarization film PNS may not cover the top surface of the first pixel defining film PDL1 disposed on the top surface of the first electrode AND disposed in each of the first emission area EA1 and the third emission area EA3.

The second pixel defining film PDL2 may be disposed on the first pixel defining film PDL1 and the planarization film PNS, the third pixel defining film PDL3 may be disposed on the second pixel defining film PDL2, and the fourth pixel defining film PDL4 may be disposed on the third pixel defining film PDL3. The first pixel defining film PDL1 and the third pixel defining film PDL3 may include or be formed of a silicon nitride (SiNx)-based inorganic film, whereas the second pixel defining film PDL2, the fourth pixel defining film PDL4, and the planarization film PNS may include or be formed of a silicon oxide (SiOx)-based inorganic film. In such an embodiment, the first pixel defining film PDL1 include or is formed of a material different from that of the planarization film PNS, and thus may serve as a stopper in a chemical mechanical polishing process for the planarization film PNS.

In an embodiment where the planarization film PNS and the second pixel defining film PDL2 are both formed as a silicon oxide (SiOx)-based inorganic film, the planarization film PNS and the second pixel defining film PDL2 may be formed as a single film.

Since the length of the third pixel defining film PDL3 in one direction is less than the length of the fourth pixel defining film PDL4 in the one direction, the bottom surface of the fourth pixel defining film PDL4 may be exposed without being covered by the third pixel defining film PDL3. That is, the third pixel defining film PDL3 and the fourth pixel defining film PDL4 may have an eaves-shaped or mushroom-shaped cross-sectional structure.

The light emitting stack IL may be disposed on the first electrode AND and the pixel defining film PDL. The light emitting stack IL may include the first stack layer IL1 and the second stack layer IL2 that emit different lights. In an embodiment where the light emitting stack IL has a two-tandem structure, one of the first stack layer IL1 and the second stack layer IL2 may emit light that includes the wavelength range of at least one selected from the first light, the second light, and the third light, and the other may emit light that includes the wavelength ranges of the other two lights. In an embodiment, for example, the first stack layer IL1 may emit light that includes the wavelength range of the first light and the wavelength range of the third light, and the second stack layer IL2 may emit light that includes the wavelength range of the second light. Here, the first light may be light of a blue wavelength band, the second light may be light of a green wavelength band, and the third light may be light of a red wavelength band.

A charge generation layer for supplying charges to the second stack layer IL2 and supplying electrons to the first stack layer IL1 may be disposed between the first stack layer IL1 and the second stack layer IL2. The charge generation layer may include an n-type charge generation layer that supplies electrons to the first stack layer IL1 and a p-type charge generation layer that supplies holes to the second stack layer IL2. The N-type charge generation layer may include a dopant of a metal material.

The first stack layer IL1 is not formed on the bottom surface of the fourth pixel defining film PDL4 that is exposed without being covered by the third pixel defining film PDL3, and thus may be cut off by the eaves-shaped or mushroom-shaped cross-sectional structure of the third pixel defining film PDL3 and the fourth pixel defining film PDL4. In this case, the first hole transport layer of the first stack layer IL1, and a charge generation layer disposed between the first stack layer IL1 and the second stack layer IL2 may also be cut off. Further, although FIG. 10 illustrates that the second stack layer IL2 is connected without being cut off, the second hole transport layer of the second stack layer IL2 may be cut off, and the second electron transport layer of the second stack layer IL2 may be connected without being cut off. Therefore, it is possible to prevent a leakage current from flowing through the first hole transport layer of the first stack layer IL1, the second hole transport layer of the second stack layer IL2, and the charge generation layer between the adjacent emission areas EA1, EA2, and EA3. Accordingly, it is possible to effectively prevent the light emitting stack IL in the adjacent emission areas EA1, EA2, and EA3 from emitting light other than the originally intended light due to the influence of the above current.

Although FIG. 10 illustrates an embodiment having a two-tandem structure in which the light emitting stack IL includes two stack layers IL1 and IL2, the present disclosure is not limited thereto. In another embodiment, for example, the light emitting stack IL may have a three-tandem structure including three stack layers as shown in FIG. 9. In such embodiments, it may be designed such that the charge generation layer between the first stack layer IL1 and the second stack layer IL2, and the charge generation layer between the second stack layer IL2 and the third stack layer IL3 are cut off by adjusting the height of the third pixel defining film PDL3. Alternatively, as shown in FIG. 9, the trench TRC penetrating the first pixel defining film PDL1, the planarization film PNS, the second pixel defining film PDL2, and the third pixel defining film PDL3 may be added. In this case, the trench TRC may penetrate at least a part of the ninth interlayer insulating film INS9, but the present disclosure is not limited thereto.

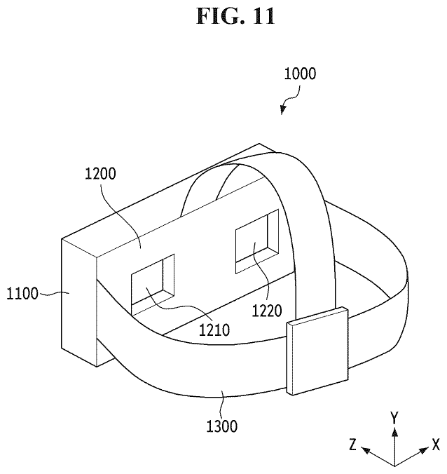

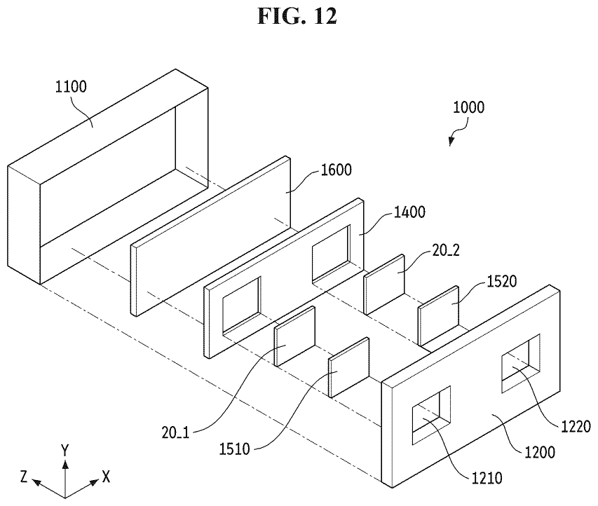

FIG. 11 is a schematic perspective view illustrating one example of a head mounted display. FIG. 12 is a schematic exploded perspective view illustrating the head mounted display shown in FIG. 11.

Referring to FIGS. 11 and 12, a head mounted display 1000 according to an embodiment includes a first display device 20_1, a second display device 20_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 20_1 provides an image to the user's left eye, and the second display device 20_2 provides an image to the user's right eye. Since each of the first display device 20_1 and the second display device 20_2 is substantially the same as the display device 20 described in conjunction with FIGS. 3 to 10, the description of the first display device 20_1 and the second display device 20_2 will be omitted.

The first optical member 1510 may be disposed between the first display device 20_1 and the first eyepiece 1210. The second optical member 1520 may be disposed between the second display device 20_2 and the second eyepiece 1220. Each of the first optical member 1510 and the second optical member 1520 may include at least one convex lens.

The middle frame 1400 may be disposed between the first display device 20_1 and the control circuit board 1600 and between the second display device 20_2 and the control circuit board 1600. The middle frame 1400 serves to support and fix the first display device 20_1, the second display device 20_2, and the control circuit board 1600.

The control circuit board 1600 may be disposed between the middle frame 1400 and the display device housing 1100. The control circuit board 1600 may be connected to the first display device 20_1 and the second display device 20_2 through the connector. The control circuit board 1600 may convert an image source inputted from the outside into the digital video data DATA, and transmit the digital video data DATA to the first display device 20_1 and the second display device 20_2 through the connector.

The control circuit board 1600 may transmit the digital video data DATA corresponding to a left-eye image optimized for the user's left eye to the first display device 20_1, and may transmit the digital video data DATA corresponding to a right-eye image optimized for the user's right eye to the second display device 20_2. Alternatively, the control circuit board 1600 may transmit the same digital video data DATA to the first display device 20_1 and the second display device 20_2.

The display device housing 1100 serves to accommodate the first display device 20_1, the second display device 20_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is located and the second eyepiece 1220 at which the user's right eye is located. FIGS. 11 and 12 illustrate an embodiment where the first eyepiece 1210 and the second eyepiece 1220 are disposed separately, but the present disclosure is not limited thereto. In another embodiment, the first eyepiece 1210 and the second eyepiece 1220 may be combined into one.

The first eyepiece 1210 may be aligned with the first display device 20_1 and the first optical member 1510, and the second eyepiece 1220 may be aligned with the second display device 20_2 and the second optical member 1520. Therefore, the user may view, through the first eyepiece 1210, the image of the first display device 20_1 magnified as a virtual image by the first optical member 1510, and may view, through the second eyepiece 1220, the image of the second display device 20_2 magnified as a virtual image by the second optical member 1520.

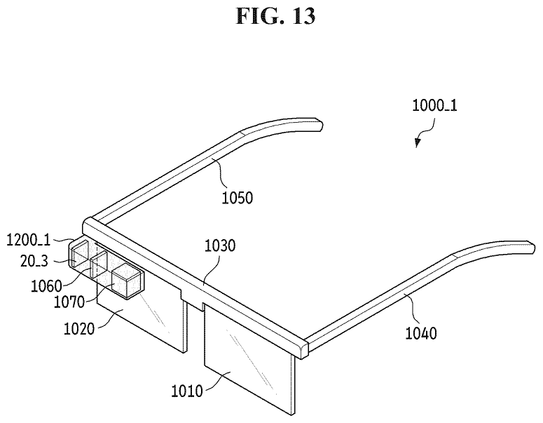

The head mounted band 1300 serves to secure the display device housing 1100 to the user's head such that the first eyepiece 1210 and the second eyepiece 1220 of the housing cover 1200 remain located on the user's left and right eyes, respectively. In a case where the display device housing 1200 is desired to be lightweight and compact, the head mounted display 1000 may be provided with, as shown in FIG. 13, an eyeglass frame instead of the head mounted band 1300.

FIG. 13 is a schematic perspective view illustrating another example of a head mounted display.

Referring to FIG. 13, a head mounted display 1000_1 according to an embodiment may be an eyeglasses-type display device in which a display device housing 1200_1 is implemented in a lightweight and compact manner. The head mounted display 1000_1 according to an embodiment may include a display device 20_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 20_3, the optical member 1060, and the optical path changing member 1070. The image displayed on the display device 20_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 20_3 and a real image seen through the right eye lens 1020 are combined.

FIG. 13 illustrates an embodiment where the display device housing 1200_1 is disposed at the right end of the support frame 1030, but the present disclosure is not limited thereto. In another embodiment, for example, the display device housing 1200_1 may be disposed at the left end of the support frame 1030, and in this case, the image of the display device 20_3 may be provided to the user's left eye. Alternatively, the display device housing 1200_1 may be disposed at both the left and right ends of the support frame 1030, and in this case, the user may view the image displayed on the display device 20_3 through both the left and right eyes.

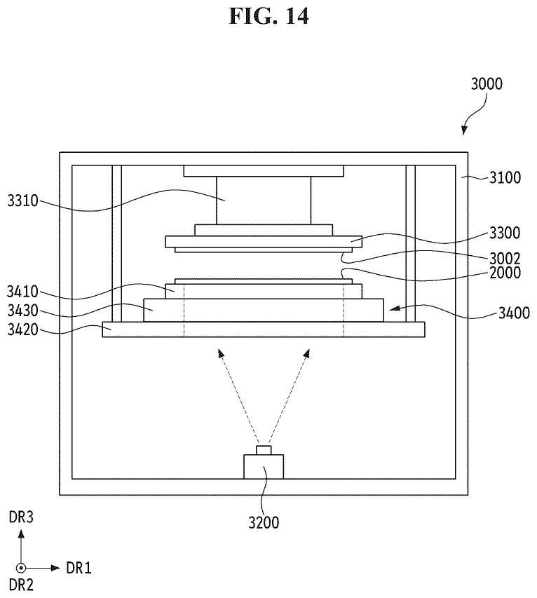

FIG. 14 is a schematic diagram illustrating a deposition mask and a deposition apparatus including the mask stage according to an embodiment of the present disclosure.

Referring to FIG. 14, an embodiment of a deposition apparatus 3000 may be used to form light emitting layers on a backplane substrate 3002 in a manufacturing process of the display panel 100 (see FIG. 3). In an embodiment, for example, as illustrated in FIG. 9, the semiconductor backplane SBP and the light emitting element backplane EBP may be disposed on the backplane substrate 3002, and the reflective electrode layer RL and the insulating films INS10 and INS11 may be disposed on the light emitting element backplane EBP. Electrode patterns, e.g., the first electrodes AND that function as anode electrodes, and the pixel defining film PDL that exposes the first electrodes AND, may be disposed on the insulating film INS11, and the first electrodes AND may be electrically connected to the reflective electrode layer RL through the vias VA10. In an embodiment, for example, the deposition apparatus 3000 may form first light emitting layers on the first electrodes AND of the first emission areas EA1. In an embodiment, for example, the deposition apparatus 3000 may form second light emitting layers on the first electrodes AND of the second emission areas EA2. In an embodiment, for example, the deposition apparatus 3000 may form third light emitting layers on the first electrodes AND of the third emission areas EA3.

The deposition apparatus 3000 may include a deposition source 3200 for providing a vapor deposition material on the backplane substrate 3002, a deposition mask 2000 disposed above the deposition source 3200, and a substrate chuck 3300 disposed above the deposition mask 2000 to support the backplane substrate 3002 in a way such that the backplane substrate 3002 faces the deposition mask 2000. That is, the substrate chuck 3300 may support the backplane substrate 3002 in a way such that the front surface of the backplane substrate 3002 faces downward, and may position the backplane substrate 3002 above the deposition mask 2000 to perform a deposition process.

The deposition source 3200, the deposition mask 2000, and the substrate chuck 3300 may be disposed in a process chamber 3100. The process chamber 3100 may have or define an internal space, and a deposition process for forming deposition material layers on the backplane substrate 3002 may be performed in the internal space of the process chamber 3100. Although not shown, the process chamber 3100 may be connected to a vacuum pump (not shown), and the internal space of the process chamber 3100 may be set to a vacuum atmosphere by the vacuum pump. An opening (not shown) for the carry-in and carry-out of the backplane substrate 3002 and the deposition mask 2000 may be provided in a wall of the process chamber 3100, and the opening may be opened and closed by a gate valve (not shown).

A deposition material may be accommodated in the deposition source 3200. The deposition source 3200 may evaporate a deposition material such as an organic material, an inorganic material, a conductive material, or the like toward the backplane substrate 3002, and the evaporated deposition material may be deposited on the backplane substrate 3002 through the deposition mask 2000. In an embodiment, for example, the deposition source 3200 may evaporate an organic material for forming light emitting layers on the backplane substrate 3002, and the evaporated organic material may be deposited on the electrode patterns on the backplane substrate 3002 through the deposition mask 2000.

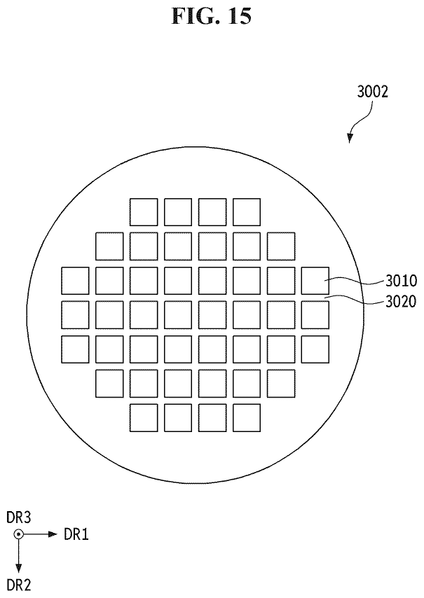

FIG. 15 is a schematic bottom view illustrating the backplane substrate shown in FIG. 14.

Referring to FIG. 15, the backplane substrate 3002 may include a plurality of display cell regions 3010 and a scribe lane region 3020 disposed between the display cell regions 3010. The display cell regions 3010 may be arranged in a matrix form along the first direction DR1 and the second direction DR2 as illustrated in FIG. 15, and may be individualized into display panels 100 (see FIG. 3) by a dicing process after the display manufacturing process is completed. For example, the first direction DR1 may be a first horizontal direction, and the second direction DR2 may be a second horizontal direction perpendicular to the first direction DR1. In addition, each of the display cell regions 3010 may have, for example, a quadrilateral planar shape as shown in the drawing.

In an embodiment, for example, each of the display cell regions 3010 may include the semiconductor backplane SBP, the light emitting element backplane EBP disposed on the semiconductor backplane SBP, the reflective electrode layer RL disposed on the light emitting element backplane EBP, and the insulating films INS10 and INS11 disposed on the reflective electrode layer RL as shown in FIG. 9. In addition, each of the display cell regions 3010 may include the plurality of electrode patterns, for example, the plurality of first electrodes AND disposed on the insulating film INS11, and the first electrodes AND may be connected to the reflective electrode layer RL through the plurality of vias VA10. In this case, the electrode patterns of the display cell regions 3010 may be disposed on the front surface of the backplane substrate 3002, and the substrate chuck 3300 may hold the rear surface of the backplane substrate 3002 such that the electrode patterns of the display cell regions 3010 face downward, i.e., face the deposition source 3200.

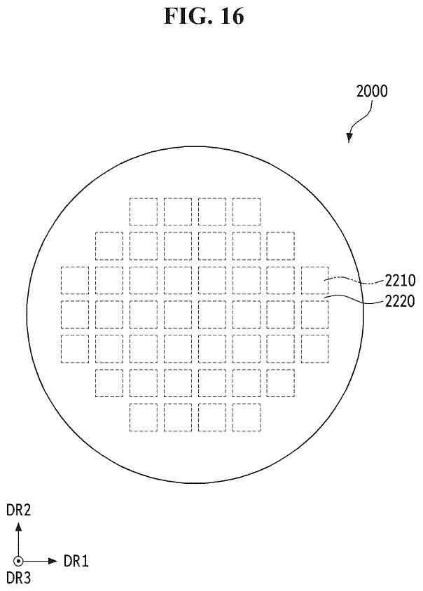

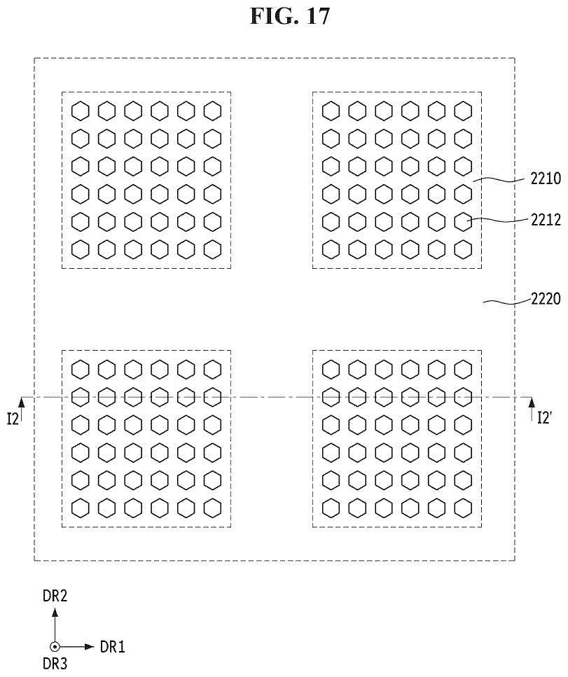

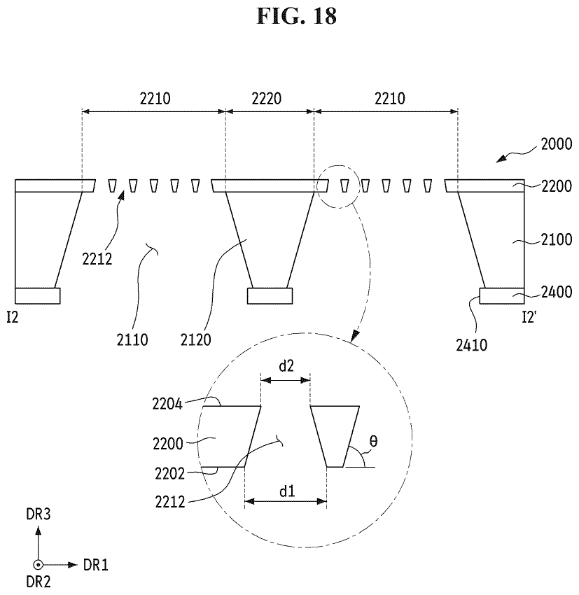

FIG. 16 is a schematic plan view illustrating the deposition mask shown in FIG. 14. FIG. 17 is a schematic enlarged plan view illustrating the mask cell regions shown in FIG. 16. FIG. 18 is a schematic cross-sectional view taken along line I2-I2′ shown in FIG. 17.

Referring to FIGS. 16 to 18, an embodiment of the deposition mask 2000 may include mask cell regions 2210 respectively corresponding to the display cell regions 3010 of the backplane substrate 3002. Each of the mask cell regions 2210 may be provided with a plurality of pixel openings 2212 exposing the first electrodes AND in the deposition process. In an embodiment, for example, the deposition mask 2000 may include a mask frame 2100 and a membrane 2200 disposed on the mask frame 2100. In such an embodiment, the membrane 2200 may include a plurality of mask cell regions 2210, and each of the mask cell regions 2210 may be provided with a plurality of pixel openings 2212.

In an embodiment, for example, the mask frame 2100 may be provided with cell openings 2110 and include a rib region 2120 defining the cell openings 2110. The membrane 2200 may include mask cell regions 2210 respectively disposed on the cell openings 2110, and a grid region 2220 surrounding the mask cell regions 2210. That is, the grid region 2220 of the membrane 2200 may be disposed on the rib region 2120 of the mask frame 2100.

The mask cell regions 2210 may be exposed toward the deposition source 3200 through the cell openings 2110, and the pixel openings 2212 may be formed to penetrate the mask cell regions 2210. That is, the pixel openings 2212 may communicate with the cell openings 2110. In this case, while performing the deposition process, the vapor deposition material provided from the deposition source 3200 may be deposited on the first electrodes AND of the backplane substrate 3002 through the cell openings 2110 and the pixel openings 2212.

As shown in FIG. 16, the mask cell regions 2210 may be arranged in a matrix form along the first direction DR1 and the second direction DR2. For example, the first direction DR1 may be the first horizontal direction, and the second direction DR2 may be the second horizontal direction perpendicular to the first direction DR1. In this case, the third direction DR3 may be a vertical direction. That is, the third direction DR3 may be a direction perpendicular to the first direction DR1 and the second direction DR2. For example, the third direction DR3 may be a thickness direction of the deposition mask 2000. The mask cell regions 2210 may have, for example, a quadrilateral planar shape as shown in the drawing, and the pixel openings 2212 may be arranged to correspond to the first electrodes AND of any of the first emission areas EA1, the second emission areas EA2, and the third emission areas EA3.

The mask frame 2100 may include or be made of single crystal silicon. In an embodiment, for example, a single crystal silicon substrate having a thickness in a range of about 700 micrometers (μm) to about 800 μm, e.g., about 775 μm, may be used as the mask frame 2100. The membrane 2200 may include or be made of silicon nitride (SiNx) and may be formed to have a thickness of about 0.5 μm to about 3 μm, for example, about 1 μm, through a thermal chemical vapor deposition (TCVD) process. The membrane 2200 may be disposed on the front surface of the mask frame 2100, and a rear inorganic film 2400 may be disposed on the rear surface of the mask frame 2100. The rear inorganic film 2400 may include or be made of silicon nitride (SiNx) and may be formed through a TCVD process. In an embodiment, for example, the membrane 2200 and the rear inorganic film 2400 may be formed simultaneously through a TCVD process. That is, the front inorganic film and the rear inorganic film 2400 may be simultaneously formed on the front surface and the rear surface of the mask frame 2100 through the TCVD process, respectively, and the front inorganic film may be used as the membrane 2200.

The pixel openings 2212 of the membrane 2200 may be formed by an anisotropic etching process. In an embodiment, for example, after forming, on the membrane 2200, a first photoresist pattern (not shown) exposing the portions where the pixel openings 2212 are to be formed, an anisotropic etching process, for example, a reactive ion etching (RIE) process, using the first photoresist pattern as an etching mask may be performed to form the pixel openings 2212 through the membrane 2200.

The rear inorganic film 2400 may be provided with rear openings 2410 corresponding to the cell openings 2110 of the mask frame 2100, and may function as an etching mask in an etching process for forming the cell openings 2110 of the mask frame 2100. In an embodiment, for example, after forming, on the rear inorganic film 2400, a second photoresist pattern (not shown) exposing the portions where the rear openings 2410 are to be formed, an anisotropic etching process, such as an RIE process, may be performed using the second photoresist pattern as an etching mask to form the rear openings 2410 through the rear inorganic film 2400.

The cell openings 2110 of the mask frame 2100 may be formed through an anisotropic etching process using the rear inorganic film 2400 as an etching mask. In an embodiment, for example, the cell openings 2110 of the mask frame 2100 may be formed by a wet etching process using an etchant including tetramethyl ammonium hydroxide (TMAH; (CH₃)₄NOH) or potassium hydroxide (KOH). The wet etching process may be performed until the membrane 2200 is exposed, such that the pixel openings 2212 of the membrane 2200 may communicate with (or connected to) the cell openings 2110 of the mask frame 2100.

According to an embodiment of the present disclosure, the membrane 2200 may be formed by the reaction between a first source gas containing silicon, such as monosilane (SiH₄), disilane (Si₂H₆), dichlorosilane (DCS; SiH₂Cl₂), or the like and a second source gas containing nitrogen, such as ammonia (NH₃). In particular, the silicon content of the membrane 2200 may be changed in the thickness direction of the membrane 2200, i.e., in the third direction DR3, and may be controlled by the supply flow rate ratio of the first source gas to the second source gas, that is, the ratio of the supply flow rate of the first source gas to the supply flow rate of the second source gas.

In an embodiment, for example, the membrane 2200 may have a first surface 2202 adjacent to (or facing) the mask frame 2100 and a second surface 2204 spaced apart from (or opposite to) the mask frame 2100 in the third direction DR3, and the silicon content of the membrane 2200 may increase in a direction from the first surface 2202 toward the second surface 2204. In such an embodiment, the first surface 2202 of the membrane 2200 may be the bottom surface of the membrane 2200, and the second surface 2204 of the membrane 2200 may be the top surface of the membrane 2200. Further, during the deposition process, the first surface 2202 of the membrane 2200 may be disposed to face the deposition source 3200, and the second surface 2204 of the membrane 2200 may be disposed adjacent to the backplane substrate 3002.

According to an embodiment of the present disclosure, the average value of the silicon content of the membrane 2200 may be greater than the silicon content of stoichiometric silicon nitride (Si₃N₄). That is, the membrane 2200 may include or be made of silicon-rich silicon nitride. In a case where the silicon content of the membrane 2200 is lower than the silicon content of the stoichiometric silicon nitride (Si₃N₄), the residual stress of the membrane 2200 may increase, and in this case, warpage may occur in the deposition mask 2000 due to the residual stress of the membrane 2200. For example, in order to substantially reduce or effectively prevent the warpage of the deposition mask 2000, the residual stress of the membrane 2200 is desired to be about 500 megapascals (MPa) or less. According to an embodiment of the present disclosure, the silicon content of the membrane 2200 may gradually increase in a direction from the first surface 2202 toward the second surface 2204, and the average value of the silicon content of the membrane 2200 may be greater than the silicon content of the stoichiometric silicon nitride (Si₃N₄). In such an embodiment, the first surface 2202 of the membrane 2200, that is, the bottom surface of the membrane 2200, has a silicon content greater than the silicon content of the stoichiometric silicon nitride (Si₃N₄) such that the warpage of the deposition mask 2000 is substantially reduced or effectively prevented.

When silicon nitride is expressed as SixNy, the ratio of the silicon content to the nitrogen content of the silicon nitride means a ‘x/y’ value, and the ratio of the silicon content to the nitrogen content of the stoichiometric silicon nitride (Si₃N₄), that is, the ‘x/y’ value, is 0.75. According to an embodiment of the present disclosure, the average ratio of the silicon content to the nitrogen content of the membrane 2200 may be controlled to be in a range of about 0.8 to about 1.2. In an embodiment, for example, the minimum ratio of the silicon content to the nitrogen content of the membrane 2200 may be about 0.8 or greater, and the maximum ratio of the silicon content to the nitrogen content of the membrane 2200 may be about 1.2 or less. That is, the ratio of the silicon content to the nitrogen content of the first surface 2202 of the membrane 2200 may be about 0.8 or greater, and the ratio of the silicon content to the nitrogen content of the second surface 2204 of the membrane 2200 may be about 1.2 or less.

The pixel openings 2212 may be formed by an RIE process using a first reaction gas containing fluorine, such as CF₄, C₂F₄, C₂F₆, C₃F₆, C₃F₈, C₄F₆, C₄F₈, C₅F₈, CH₃F, CH₂F₂, C₂HF₅, CHF₃, NF₃, SF₆, or the like, a second reaction gas containing oxygen, such as O₂, NO, NO₂, or the like, and a sputtering gas, such as He, Ne, Ar, Xe, or the like. In this case, the etching speed of the membrane 2200 may vary depending on the silicon content of the membrane 2200. In particular, the silicon content of the membrane 2200 and the etching speed of the membrane 2200 may be inversely proportional. Accordingly, the etching speed may be relatively slow at the second surface 2204 of the membrane 2200 having a relatively high silicon content, and may be relatively fast at the first surface 2202 of the membrane 2200 having a relatively low silicon content. Further, isotropic etching by the first reaction gas containing fluorine may actively occur in a direction from the second surface 2204 of the membrane 2200 toward the first surface 2202 thereof, such that each of the pixel openings 2212 may have a width that gradually increases in a direction from the second surface 2204 of the membrane 2200 toward the first surface 2202 thereof.

In an embodiment, for example, the pixel openings 2212 may be formed by an RIE process such that the inner surface of each of the pixel openings 2212 has an inclination angle θ of about 30° to about 85° with respect to the first surface 2202 of the membrane 2200. The inner surface inclination angle θ of the pixel openings 2212 may be appropriately controlled by the flow rate of the first reaction gas, the silicon content of the membrane 2200, the plasma power, the bias power, or the like. According to an embodiment of the present disclosure, as illustrated in FIG. 18, each of the pixel openings 2212 may have a lower width d1 greater than an upper width d2, so that the amount of deposition material blocked by the membrane 2200 during the deposition process may be considerably reduced, and the size and thickness of deposition material layers formed on the backplane substrate 3002 may be more uniformly and precisely controlled.

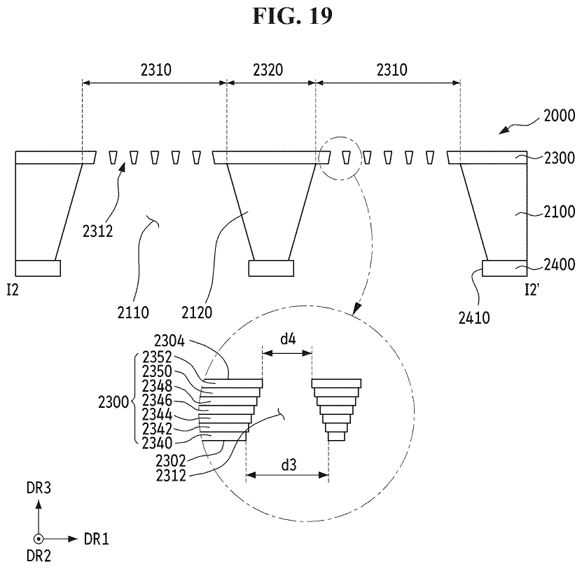

FIG. 19 is a cross-sectional view illustrating a deposition mask according to an embodiment of the present disclosure.

Referring to FIG. 19, a deposition mask 2000 according to an embodiment of the present disclosure may include a mask frame 2100 provided with cell openings 2110, a membrane 2300 disposed on the front surface of the mask frame 2100, and a rear inorganic film 2400 disposed on the rear surface of the mask frame 2100. The mask frame 2100 may include a rib region 2120 defining the cell openings 2110, and the membrane 2300 may include mask cell regions 2310 disposed on the cell openings 2110 and a grid region 2320 disposed on the rib region 2120. Each of the mask cell regions 2310 may be provided with a plurality of pixel openings 2312 respectively communicating with the cell openings 2110, and the rear inorganic film 2400 may be provided with rear openings 2410 exposing the cell openings 2110. In such an embodiment, the mask frame 2100 and the rear inorganic film 2400 except the membrane 2300 are substantially the same as those described above with reference to FIGS. 16 to 18, and any repetitive detailed description thereof will be omitted.

According to an embodiment, the membrane 2300 may include or be made of silicon nitride, and may have a first surface 2302 adjacent to the mask frame 2100 and a second surface 2304 spaced apart from the mask frame 2100 in the third direction DR3. In particular, the silicon content of the membrane 2300 may increase in a direction from the first surface 2302 toward the second surface 2304. In an embodiment, for example, the membrane 2300 may include a plurality of silicon nitride films 2340, 2342, 2344, 2346, 2348, 2350, and 2352 stacked on the mask frame 2100, and the silicon contents of the silicon nitride films 2340 to 2352 may be increased in a stepwise manner in a direction from the first surface 2302 of the membrane 2300 toward the second surface 2304 of the membrane 2300.

The silicon nitride films 2340 to 2352 may be formed by the reaction between a first source gas containing silicon, such as monosilane (SiH₄), disilane (Si₂H₆), dichlorosilane (DCS; SiH₂Cl₂), or the like, and a second source gas containing nitrogen, such as ammonia (NH₃). The silicon contents of the silicon nitride films 2340 to 2352 may be controlled by the supply flow rate ratio of the first source gas to the second source gas. In an embodiment, for example, during the formation of the silicon nitride films 2340 to 2352, the supply flow rate of the second source gas may be maintained constant, and the supply flow rate of the first source gas may be increased in a stepwise manner.

In an embodiment, as shown in FIG. 19, the membrane 2300 includes seven layers of silicon nitride films 2340 to 2352, but the number of silicon nitride films 2340 to 2352 may be variously changed, and the scope of the present disclosure is not limited thereby. In an embodiment, for example, each of the silicon nitride films 2340 to 2352 may be formed to have a thickness of about 100 nm to about 300 nm, and the membrane 2300 may be formed to have a total thickness of about 0.5 μm to about 3 μm, e.g., about 1 μm.

The average value of the silicon contents of the silicon nitride films 2340 to 2352 may be greater than the silicon content of the stoichiometric silicon nitride (Si₃N₄). Further, in order to substantially reduce or effectively prevent the warpage of the deposition mask 2000, it is preferable that the total residual stress of the silicon nitride films 2340 to 2352 is about 500 MPa or less. In an embodiment, for example, the average ratio of the silicon contents to the nitrogen contents of the silicon nitride films 2340 to 2352 may be controlled within a range of about 0.8 to about 1.2.

For another example, in order to substantially reduce or effectively prevent the warpage of the deposition mask 2000, the silicon nitride film 2340 having the first surface 2302 of the membrane 2300 among the silicon nitride films 2340 to 2352, i.e., the lowermost silicon nitride film 2340, may have a silicon content greater than the silicon content of stoichiometric silicon nitride (Si₃N₄), and the silicon contents of the silicon nitride films 2340 to 2352 may be increased in a stepwise manner in a direction from the lowermost silicon nitride film 2340 toward the uppermost silicon nitride film 2352, i.e., the silicon nitride film 2352 having the second surface 2304 of the membrane 2300. That is, the silicon nitride films 2340 to 2352 may all include or be made of silicon-rich silicon nitride. In an embodiment, for example, the ratio of the silicon content to the nitrogen content of the lowermost silicon nitride film 2340 among the silicon nitride films 2340 to 2352 may be about 0.8 or greater, and the ratio of the silicon content to the nitrogen content of the uppermost silicon nitride film 2352 among the silicon nitride films 2340 to 2352 may be about 1.2 or less.

The pixel openings 2312 may be formed by an RIE process using a first reaction gas containing fluorine, such as CF₄, C₂F₄, C₂F₆, C₃F₆, C₃F₈, C₄F₆, C₄F₈, C₅F₈, CH₃F, CH₂F₂, C₂HF₅, CHF₃, NF₃, SF₆, or the like, a second reaction gas containing oxygen, such as O₂, NO, NO₂, or the like, and a sputtering gas, such as He, Ne, Ar, Xe, or the like. In this case, the etching speed of the silicon nitride films 2340 to 2352 may vary depending on the silicon contents of the silicon nitride films 2340 to 2352.

According to an embodiment, the etching speed may be increased in a stepwise manner from the uppermost silicon nitride film 2352 toward the lowermost silicon nitride film 2340, so that each of the pixel openings 2312 may have a width that increases in a stepwise manner in a direction from the second surface 2304 of the membrane 2300 toward the first surface 2302 of the membrane 2300. As a result, each of the pixel openings 2312 of the membrane 2300 may have a lower width d3 greater than an upper width d4, as illustrated in FIG. 19. That is, the lower portions of the pixel openings 2312 penetrating the lowermost silicon nitride film 2340 may have the width d3 greater than the width d4 of the upper portions of the pixel openings 2312 penetrating the uppermost silicon nitride film 2352, so that the amount of deposition material blocked by the membrane 2300 during the deposition process may be considerably reduced, and the size and thickness of deposition material layers formed on the backplane substrate 3002 may be more uniformly and precisely controlled.

Referring back to FIG. 14, the substrate chuck 3300 may be disposed above the deposition source 3200 and may support the backplane substrate 3002, in a way such that the backplane substrate 3002 faces the deposition source 3200. In an embodiment, for example, the substrate chuck 3300 may be an electrostatic chuck configured to hold the rear surface of the backplane substrate 3002 using an electrostatic force. To elaborate, the electrode patterns, i.e., the first electrodes AND may be disposed on the front surface of the backplane substrate 3002, and the substrate chuck 3300 may hold the rear surface of the backplane substrate 3002 so that the front surface of the backplane substrate 3002 faces the deposition source 3200, i.e., faces downward.

Although not shown, the backplane substrate 3002 may be loaded into the process chamber 3100 by a transfer robot, and lift fingers (not shown) for transferring the backplane substrate 3002 from the transfer robot to the substrate chuck 3300 may be disposed in the process chamber 3100. In an embodiment, for example, the backplane substrate 3002 may be placed on the lift fingers after being brought into the process chamber 3100 by the transfer robot, and the lift fingers may be raised to load the backplane substrate 3002 on the substrate chuck 3300. Subsequently, the substrate chuck 3300 may hold the rear surface of the backplane substrate 3002 by using the electrostatic force.

An upper driving unit 3310 for moving and rotating the substrate chuck 3300 may be disposed above the substrate chuck 3300 to adjust the position and angle of the backplane substrate 3002. In an embodiment, for example, the upper driving unit 3310 may move the substrate chuck 3300 in the first and second directions DR1 and DR2 to adjust the horizontal position of the backplane substrate 3002, and may move the substrate chuck 3300 in the third direction DR3 to adjust the vertical position of the backplane substrate 3002. In this case, the first direction DR1, the second direction DR2, and the third direction DR3 may be an X-axis direction, a Y-axis direction, and a Z-axis direction, respectively.

In addition, the upper driving unit 3310 may rotate the substrate chuck 3300 around the Z-axis to adjust the azimuthal angle of the backplane substrate 3002. Further, in order to adjust the inclination of the backplane substrate 3002, the upper driving unit 3310 may rotate the substrate chuck 3300 around the X-axis, and may rotate the substrate chuck 3300 around the Y-axis. In an embodiment, for example, the upper driving unit 3310 may include a hexapod actuator that provides a motion of 6 degrees of freedom (X, Y, Z, θx, θy, and θz).

A mask stage 3400 on which the deposition mask 2000 is placed may be disposed above the deposition source 3200. That is, the mask stage 3400 may be disposed under the substrate chuck 3300 and may support an edge portion of the deposition mask 2000. The deposition mask 2000 may be carried into the process chamber 3100 by the transfer robot. In an embodiment, for example, the deposition mask 2000 brought into the process chamber 3100 by the transfer robot may be placed on the lift fingers, and the lift fingers may be lowered to load the deposition mask 2000 on the mask stage 3400.

The mask stage 3400 may include a mask chuck 3410 for supporting the deposition mask 2000. Although not shown in detail, the mask chuck 3410 may have a circular ring shape to support the edge portion of the deposition mask 2000. In an embodiment, for example, the mask chuck 3410 may be an electrostatic chuck configured to hold the edge portion of the deposition mask 2000 using an electrostatic force.

The mask stage 3400 may include a support plate 3420 for supporting the mask chuck 3410. The support plate 3420 may have an opening to allow the mask cell regions 2310 of the deposition mask 2000 to be exposed toward the deposition source 3200, and a lower driving unit 3430 for adjusting the position and angle of the deposition mask 2000 may be disposed between the support plate 3420 and the mask chuck 3410. In an embodiment, for example, the lower driving unit 3430 may move the mask chuck 3410 in the first and second directions DR1 and DR2 to adjust the horizontal position of the deposition mask 2000, and may rotate the mask chuck 3410 around the Z-axis to adjust the azimuthal angle of the deposition mask 2000. In an embodiment, for example, the lower driving unit 3430 may include a piezo actuator that provides a motion of 3 degrees of freedom (X, Y, and θz), and the piezo actuator may have a quadrilateral ring shape.

After the backplane substrate 3002 and the deposition mask 2000 are loaded onto the substrate chuck 3300 and the mask chuck 3410, the upper driving unit 3310 may lower the substrate chuck 3300 to a preset height, and adjust the inclination of the substrate chuck 3300 in order to adjust the parallelism between the substrate chuck 3300 and the mask chuck 3410. In an embodiment, for example, although not shown, a plurality of gap sensors (not shown) for measuring the gap between the substrate chuck 3300 and the mask chuck 3410 may be mounted at the substrate chuck 3300, and the upper driving unit 3310 may adjust the parallelism between the substrate chuck 3300 and the mask chuck 3410 based on the measured values of the gap sensors.

In addition, the upper driving unit 3310 or the lower driving unit 3430 may perform alignment between the backplane substrate 3002 and the deposition mask 2000. In an embodiment, for example, although not shown, a plurality of substrate alignment keys (not shown) may be arranged on the edge portion of the backplane substrate 3002, and a plurality of mask alignment keys (not shown) corresponding to the plurality of substrate alignment keys may be arranged on the edge portion of the deposition mask 2000. The deposition apparatus 3000 may include a camera unit (not shown) for detecting the substrate alignment key and the mask alignment key, and an illumination unit (not shown) for illuminating the substrate alignment key and the mask alignment key, and the substrate chuck 3300 or the mask chuck 3410 may be provided with through holes (not shown) for providing illumination light and detecting the substrate alignment key and the mask alignment key.

In an embodiment, for example, the illumination unit may provide near infrared (NIR) or short wave infrared (SWIR) light, e.g., infrared light having a wavelength of about 1000 nm to about 1200 nm, and the camera unit may detect infrared light transmitted through the backplane substrate 3002 and the deposition mask 2000. The upper driving unit 3310 or the lower driving unit 3430 may perform positional alignment between the backplane substrate 3002 and the deposition mask 2000 based on positional information of the substrate alignment key and the mask alignment key acquired by the camera unit.

As described above, after the parallelism adjustment between the substrate chuck 3300 and the mask chuck 3410 and the positional alignment between the backplane substrate 3002 and the deposition mask 2000 are performed, the backplane substrate 3002 may be positioned on the deposition mask 2000. In an embodiment, for example, the upper driving unit 3310 may adjust the height of the substrate chuck 3300 such that the gap between the backplane substrate 3002 and the deposition mask 2000 becomes a preset gap, e.g., a gap of several micrometers (μm). In an embodiment, for example, the upper driving unit 3310 may adjust the height of the substrate chuck 3300 such that the backplane substrate 3002 is brought into contact with the deposition mask 2000.

After the backplane substrate 3002 is positioned on the deposition mask 2000, the deposition source 3200 may provide a vapor deposition material onto the backplane substrate 3002 through the deposition mask 2000, thereby forming a deposition material layer on the backplane substrate 3002. In an embodiment, for example, the deposition source 3200 may evaporate an organic material for forming light emitting layers on the backplane substrate 3002, and the evaporated organic material may be deposited on the electrode patterns of the backplane substrate 3002 through the pixel openings 2212 of the deposition mask 2000.

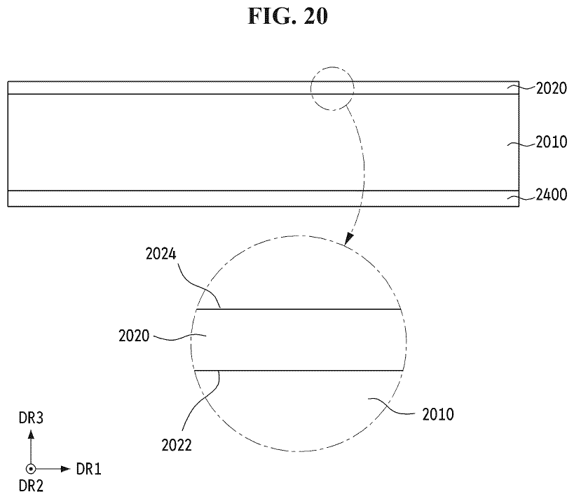

FIGS. 20 to 23 are schematic cross-sectional views illustrating a method of manufacturing a deposition mask according to an embodiment of the present disclosure.

Referring to FIG. 20, an inorganic film 2020 may be formed on a mask substrate 2010. The mask substrate 2010 may include or be made of single crystal silicon. In an embodiment, for example, a single crystal silicon substrate having a thickness of about 700 μm to about 800 μm, e.g., a thickness of about 775 μm, may be used as the mask substrate 2010, and may function as the mask frame 2100 (see FIG. 18) of the deposition mask 2000. The inorganic film 2020 may be formed to have a thickness of about 0.5 μm to about 3 μm on the mask substrate 2010 by a TCVD process, and may be used as the membrane 2200 (see FIG. 18) of the deposition mask 2000.

The inorganic film 2020 may contain silicon nitride (SiNx). The first source gas containing silicon, such as monosilane (SiH₄), disilane (Si₂H₆), dichlorosilane (DCS; SiH₂Cl₂), or the like and the second source gas containing nitrogen, such as ammonia (NH₃), may be supplied into the process chamber of the deposition apparatus for performing the TCVD process, and the inorganic film 2020 may be formed by the reaction between the first source gas and the second source gas. In an embodiment, for example, dichlorosilane (DCS; SiH₂Cl₂) gas may be used as the first source gas. In another embodiment, for example, a mixed gas of dichlorosilane (DCS; SiH₂Cl₂) and monosilane (SiH₄) may be used as the first source gas.

The inorganic film 2020 may be formed on the front surface of the mask substrate 2010, and the rear inorganic film 2400 may be formed on the rear surface of the mask substrate 2010. In this case, the inorganic film 2020 may be a front inorganic film. In an embodiment, for example, the rear inorganic film 2400 may include silicon nitride, and may be formed simultaneously with the inorganic film 2020 by the TCVD process.

The inorganic film 2020 may be a silicon-rich silicon nitride film, and the TCVD process may be performed at a low pressure and a high temperature to form a silicon-rich silicon nitride film on the mask substrate 2010. In an embodiment, for example, the TCVD process may be performed in a pressure atmosphere of about 210 millitorr (mTorr) to about 250 mTorr and a temperature atmosphere of about 800° C. to about 850° C. Further, the supply flow rate ratio of the first source gas to the second source gas may be appropriately adjusted within a range of about 1 to about 10 such that the residual stress of the inorganic film 2020 becomes about 500 MPa or less.

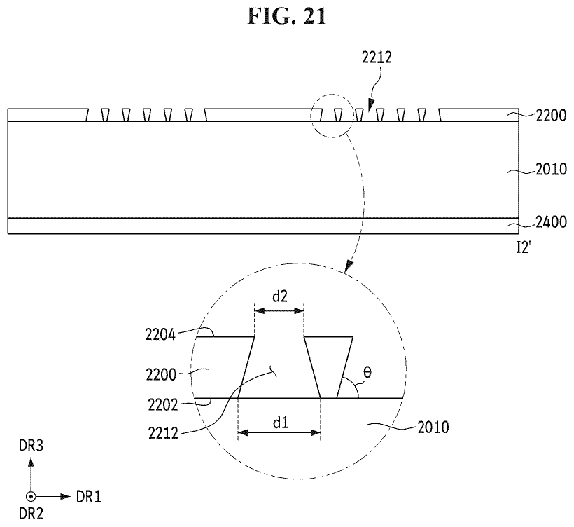

The inorganic film 2020 may have a first surface 2022 adjacent to the mask substrate 2010 and a second surface 2024 spaced apart from the mask substrate 2010 in the third direction DR3. In this case, the first surface 2022 of the inorganic film 2020 may be the same surface as the first surface 2202 (see FIG. 21) of the membrane 2200, and the second surface 2024 of the inorganic film 2020 may be the same surface as the second surface 2204 (see FIG. 21) of the membrane 2200.

According to an embodiment, the silicon content of the inorganic film 2020 may gradually increase in a direction from the first surface 2022 of the inorganic film 2020 toward the second surface 2024 of the inorganic film 2020, and the average value of the silicon content of the inorganic film 2020 may be greater than the silicon content of the stoichiometric silicon nitride (Si₃N₄). Specifically, the ratio of the silicon content to the nitrogen content of the stoichiometric silicon nitride (Si₃N₄) is 0.75, and the average ratio of the silicon content to the nitrogen content of the inorganic film 2020 may be controlled to be in a range of about 0.8 to about 1.2. In this case, the ratio of the silicon content to the nitrogen content at the first surface 2022 of the inorganic film 2020, i.e., the bottom surface of the inorganic film 2020, is desired to be greater than 0.75 to substantially reduce or effectively prevent the warpage of the deposition mask 2000.

In an embodiment, for example, the minimum ratio of the silicon content to the nitrogen content of the inorganic film 2020 may be about 0.8 or greater, and the maximum ratio of the silicon content to the nitrogen content of the inorganic film 2020 may be about 1.2 or less. That is, the ratio of the silicon content to the nitrogen content of the first surface 2022 of the inorganic film 2020 may be about 0.8 or greater, and the ratio of the silicon content to the nitrogen content of the second surface 2024 of the inorganic film 2020 may be about 1.2 or less.

The silicon content of the inorganic film 2020 may be controlled by the supply flow rates of the first source gas and the second source gas supplied onto the mask substrate 2010 during the TCVD process. Specifically, the supply flow rate ratio of the first source gas to the second source gas may be gradually increased such that the silicon content of the inorganic film 2020 gradually increases from the first surface 2022 of the inorganic film 2020 toward the second surface 2024 of the inorganic film 2020 during the formation of the inorganic film 2020. In an embodiment, for example, during the formation of the inorganic film 2020, the supply flow rate ratio of the first source gas to the second source gas may be gradually increased within a range of about 1 to about 10.

Referring to FIG. 21, the inorganic film 2020 may be patterned to form the membrane 2200 from the inorganic film 2020 on the mask substrate 2010. Specifically, the inorganic film 2020 may be patterned to form the membrane 2200 with the plurality of pixel openings 2212 that expose the front surface of the mask substrate 2010. In this case, the membrane 2200 may have the first surface 2202 adjacent to the mask substrate 2010 and the second surface 2204 spaced apart from the mask substrate 2010 in the third direction DR3, and each of the pixel openings 2212 may have a width that gradually increases in a direction from the second surface 2204 of the membrane 2200 toward the first surface 2202 of the membrane 2200.

The pixel openings 2212 of the membrane 2200 may be formed by an anisotropic etching process. In an embodiment, for example, after a first photoresist pattern (not shown) that exposes portions where the pixel openings 2212 are to be formed on the inorganic film 2020 is formed, an anisotropic etching process, e.g., an RIE process, using the first photoresist pattern as an etching mask may be performed, thereby forming the pixel openings 2212 that expose front portions of the mask substrate 2010. That is, the inorganic film 2020 may be partially removed by the RIE process, so that the membrane 2200 with the plurality of pixel openings 2212 may be formed on the mask substrate 2010. The first photoresist pattern may be removed by a stripping and/or ashing process after the pixel openings 2212 are formed.

In an embodiment, for example, the pixel openings 2212 may be formed by an RIE process using a first reaction gas containing fluorine, such as CF₄, C₂F₄, C₂F₆, C₃F₆, C₃F₈, C₄F₆, C₄F₈, C₅F₈, CH₃F, CH₂F₂, C₂HF₅, CHF₃, NF₃, SF₆, or the like, a second reaction gas containing oxygen, such as O₂, NO, NO₂, or the like, and a sputtering gas, such as He, Ne, Ar, Xe, or the like. The etching speed of the inorganic film 2020 may vary depending on the silicon content of the inorganic film 2020. In particular, the silicon content of the inorganic film 2020 and the etching speed of the inorganic film 2020 may be inversely proportional. Accordingly, the etching speed may be relatively slow at the second surface 2024 of the inorganic film 2020 having a relatively high silicon content, and may be relatively fast at the first surface 2022 of the inorganic film 2020 having a relatively low silicon content. Further, isotropic etching by the first reaction gas containing fluorine may actively occur in a direction from the second surface 2024 of the inorganic film 2020 toward the first surface 2022 thereof, such that each of the pixel openings 2212 may have a width that gradually increases in a direction from the second surface 2024 of the inorganic film 2020 toward the first surface 2022 thereof.

In an embodiment, for example, the pixel openings 2212 may be formed by an RIE process such that the inner surface of each of the pixel openings 2212 has an inclination angle θ of about 30 ° to about 85 ° with respect to the first surface 2202 of the membrane 2200. The inner surface inclination angle θ of the pixel openings 2212 may be appropriately controlled by the flow rate of the first reaction gas, the silicon content of the inorganic film 2020, the plasma power, the bias power, or the like. According to an embodiment, as shown in FIG. 21, each of the pixel openings 2212 may be formed to have the lower width d1 greater than the upper width d2.

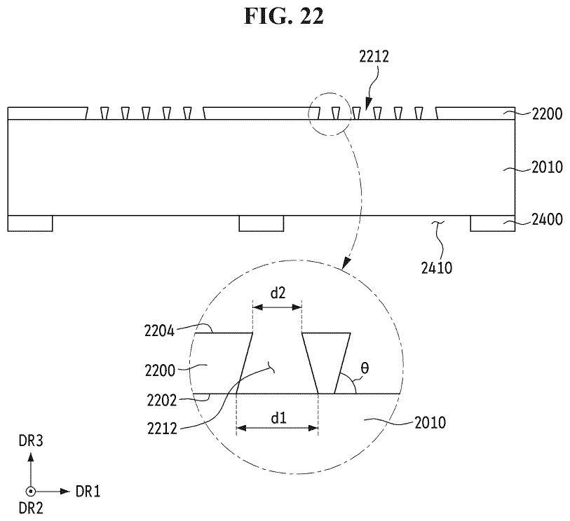

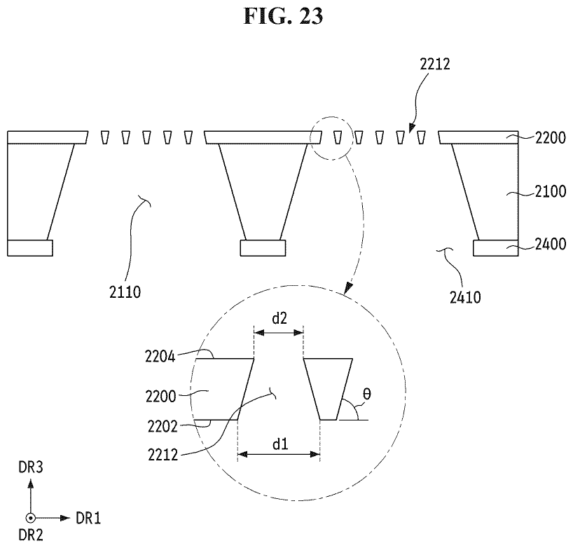

Referring to FIGS. 22 and 23, the mask substrate 2010 may be patterned to form the mask frame 2100 from the mask substrate 2010. Specifically, the mask substrate 2010 may be patterned to form the mask frame 2100 with the cell openings 2110 communicating with the pixel openings 2212. In an embodiment, for example, after forming on the rear inorganic film 2400 a second photoresist pattern (not shown) exposing the portions where the rear openings 2410 are to be formed, an anisotropic etching process, such as an RIE process, may be performed using the second photoresist pattern as an etching mask, thereby forming the rear openings 2410 that expose rear portions of the mask substrate 2010, as shown in FIG. 22. The second photoresist pattern may be removed through a stripping and/or ashing process after the rear openings 2410 are formed.

The RIE process for forming the rear openings 2410 may be performed using a first reaction gas containing fluorine, such as CF₄, C₂F₄, C₂F₆, C₃F₆, C₃F₈, C₄F₆, C₄F₈, C₅F₈, CH₃F, CH₂F₂, C₂HF₅, CHF₃, NF₃, SF₆, or the like, a second reaction gas containing oxygen, such as O₂, NO, NO₂, or the like, and a sputtering gas, such as He, Ne, Ar, Xe, or the like. In particular, a relatively high bias power may be used such that the inner surfaces of the rear openings 2410 are formed in the third direction DR3 during the RIE process, that is, the inner surfaces of the rear openings 2410 become perpendicular to the rear surface of the mask substrate 2010. The bias power may be applied to a chuck (not shown) on which the mask substrate 2010 is placed during the RIE process.

After the rear openings 2410 are formed, the cell openings 2110 communicating with the pixel openings 2212 may be formed, as illustrated in FIG. 23. In an embodiment, for example, the cell openings 2110 may be formed by a wet etching process using an etchant including TMAH ((CH₃)₄NOH) or potassium hydroxide (KOH). The wet etching process may be performed until the membrane 2200 is exposed, such that the pixel openings 2212 of the membrane 2200 may communicate with the cell openings 2110 of the mask frame 2100. In this case, the rear inorganic film 2400 may function as an etching mask in the wet etching process.

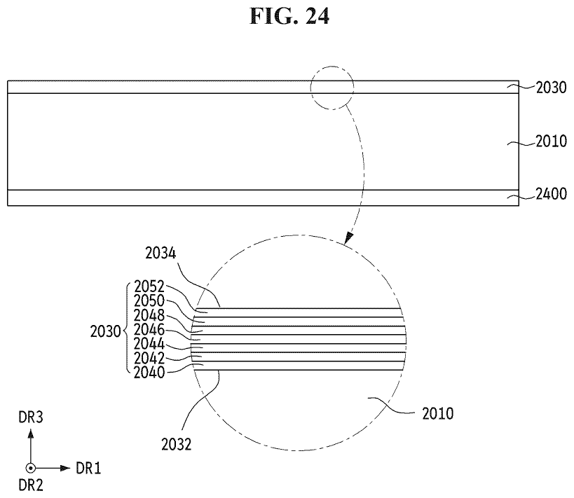

FIGS. 24 to 27 are schematic cross-sectional views illustrating a method of manufacturing a deposition mask according to another embodiment of the present disclosure.

Referring to FIG. 24, an inorganic film 2030 may be formed on a mask substrate 2010. The mask substrate 2010 may include or be made of single crystal silicon. In an embodiment, for example, a single crystal silicon substrate having a thickness of about 700 μm to about 800 μm, e.g., a thickness of about 775μm, may be used as the mask substrate 2010, and may function as the mask frame 2100 (see FIG. 19) of the deposition mask 2000. The inorganic film 2030 may be formed to have a thickness of about 0.5 μm to about 3 μm on the mask substrate 2010 by a TCVD process, and may be used as the membrane 2300 (see FIG. 19) of the deposition mask 2000.

The inorganic film 2030 may include silicon nitride (SiNx). The first source gas containing silicon, such as monosilane (SiH₄), disilane (Si₂H₆), dichlorosilane (DCS; SiH₂Cl₂), or the like and the second source gas containing nitrogen, such as ammonia (NH₃), may be supplied into the process chamber of the deposition apparatus for performing the TCVD process, and the inorganic film 2030 may be formed by the reaction between the first source gas and the second source gas. In an embodiment, for example, dichlorosilane (DCS; SiH₂Cl₂) gas may be used as the first source gas. In another embodiment, for example, a mixed gas of dichlorosilane (DCS; SiH₂Cl₂) and monosilane (SiH₄) may be used as the first source gas.

The inorganic film 2030 may be formed on the front surface of the mask substrate 2010, and the rear inorganic film 2400 may be formed on the rear surface of the mask substrate 2010. In this case, the inorganic film 2030 may be a front inorganic film. In an embodiment, for example, the rear inorganic film 2400 may include silicon nitride, and may be formed simultaneously with the inorganic film 2030 by the TCVD process.

The inorganic film 2030 may be a silicon-rich silicon nitride film, and the TCVD process may be performed at a low pressure and a high temperature to form a silicon-rich silicon nitride film on the mask substrate 2010. In an embodiment, for example, the TCVD process may be performed in a pressure atmosphere of about 210 mTorr to about 250 mTorr and a temperature atmosphere of about 800° C. to about 850° C.

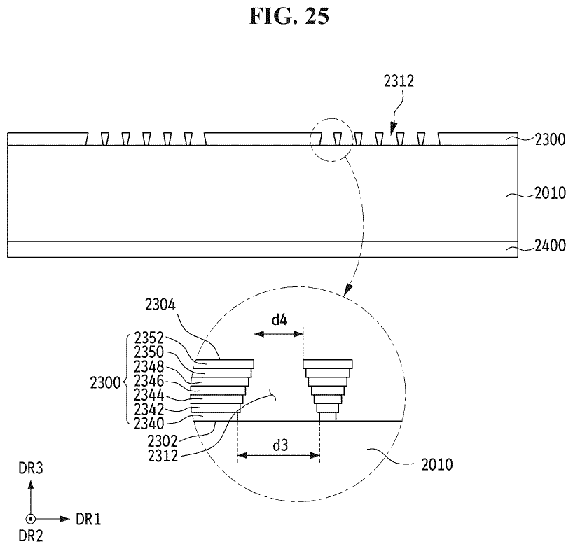

The inorganic film 2030 may have a first surface 2032 adjacent to the mask substrate 2010 and a second surface 2034 spaced apart from the mask substrate 2010 in the third direction DR3. In this case, the first surface 2032 of the inorganic film 2030 may be the same surface as the first surface 2302 (see FIG. 25) of the membrane 2300, and the second surface 2034 of the inorganic film 2030 may be the same surface as the second surface 2304 (see FIG. 25) of the membrane 2300.

According to an embodiment, the silicon content of the inorganic film 2030 may be increased in a stepwise manner in a direction from the first surface 2032 of the inorganic film 2030 toward the second surface 2034 of the inorganic film 2030. In an embodiment, for example, the inorganic film 2030 may include a plurality of silicon nitride films 2040, 2042, 2044, 2046, 2048, 2050, and 2052 stacked on the mask substrate 2010, and the silicon contents of the silicon nitride films 2040 to 2052 may be increased in a stepwise manner in a direction from the first surface 2032 of the inorganic film 2030 toward the second surface 2034 of the inorganic film 2030.

During the TCVD process for forming the silicon nitride films 2040 to 2052, the silicon contents of the silicon nitride films 2040 to 2052 may be controlled by the supply flow rate ratio of the first source gas to the second source gas. In an embodiment, for example, during the formation of the silicon nitride films 2040 to 2052, the supply flow rate of the second source gas may be maintained constant, and the supply flow rate of the first source gas may be increased in a stepwise manner. In an embodiment, for example, during the TCVD process, the supply flow rate of the first source gas to the second source gas may be increased in a stepwise manner within a range of about 1 to about 10, such that the plurality of silicon nitride films 2040 to 2052 may be formed on the mask substrate.

In an embodiment, as shown in FIG. 24, the inorganic film 2030 includes seven layers of silicon nitride films 2040 to 2052, but the number of silicon nitride films 2040 to 2052 may be variously changed, and the scope of the present disclosure is not limited thereby. In an embodiment, for example, each of the silicon nitride films 2040 to 2052 may be formed to have a thickness of about 100 nm to about 300 nm, and the inorganic film 2030 may be formed to have a thickness of about 0.5 μm to about 3 μm, e.g., about 1 μm.

The average value of the silicon contents of the silicon nitride films 2040 to 2052 may be greater than the silicon content of the stoichiometric silicon nitride (Si₃N₄). Further, in order to reduce or prevent the warpage of the deposition mask 2000, it is preferable that the total residual stress of the silicon nitride films 2040 to 2052 is about 500 MPa or less. In an embodiment, for example, the average ratio of the silicon contents to the nitrogen contents of the silicon nitride films 2040 to 2052 may be controlled to be in a range of about 0.8 to about 1.2.

In an embodiment, for example, in order to reduce or prevent the warpage of the deposition mask 2000, the silicon nitride film 2040 having the first surface 2032 of the inorganic film 2030 among the silicon nitride films 2040 to 2052, i.e., the lowermost silicon nitride film 2040, may have a silicon content greater than the silicon content of stoichiometric silicon nitride (Si₃N₄), and the silicon contents of the silicon nitride films 2040 to 2052 may be increased in a stepwise manner in a direction from the lowermost silicon nitride film 2040 toward the uppermost silicon nitride film 2052, i.e., the silicon nitride film 2052 having the second surface 2034 of the inorganic film 2030. That is, the silicon nitride films 2040 to 2052 may all include or be made of silicon-rich silicon nitride. In an embodiment, for example, the ratio of the silicon content to the nitrogen content of the lowermost silicon nitride film 2040 among the silicon nitride films 2040 to 2052 may be about 0.8 or greater, and the ratio of the silicon content to the nitrogen content of the uppermost silicon nitride film 2052 among the silicon nitride films 2040 to 2052 may be about 1.2 or less.

Referring to FIG. 25, the inorganic film 2030 may be patterned to form the membrane 2300 from the inorganic film 2030 on the mask substrate 2010. Specifically, the inorganic film 2030 may be patterned to form the membrane 2300 with the plurality of pixel openings 2312 that expose the front surface of the mask substrate 2010. In this case, the membrane 2300 may have the first surface 2302 adjacent to the mask substrate 2010 and the second surface 2304 spaced apart from the mask substrate 2010 in the third direction DR3, and each of the pixel openings 2312 may have a width that increases in a stepwise manner in a direction from the second surface 2304 of the membrane 2300 toward the first surface 2302 of the membrane 2300. Further, the membrane 2300 may include the plurality of silicon nitride films 2340, 2342, 2344, 2346, 2348, 2350, 2352, and the silicon nitride films 2340 to 2352 of the membrane 2300 are the same films as the silicon nitride films 2040 to 2052 of the inorganic film 2030. That is, the pixel openings 2312 may be formed to penetrate the silicon nitride films 2340 to 2352 of the membrane 2300.

The pixel openings 2312 of the membrane 2300 may be formed through an anisotropic etching process. In an embodiment, for example, after a first photoresist pattern (not shown) that exposes portions where the pixel openings 2312 are to be formed on the inorganic film 2030 is formed, an anisotropic etching process, e.g., an RIE process, using the first photoresist pattern as an etching mask may be performed, thereby forming the pixel openings 2312 that expose front portions of the mask substrate 2010. That is, the inorganic film 2030 may be partially removed by the RIE process, such that the membrane 2300 with the plurality of pixel openings 2312 may be formed on the mask substrate 2010. The first photoresist pattern may be removed by a stripping and/or ashing process after the pixel openings 2312 are formed.

In an embodiment, for example, the pixel openings 2312 may be formed by an RIE process using a first reaction gas containing fluorine, such as CF₄, C₂F₄, C₂F₆, C₃F₆, C₃F₈, C₄F₆, C₄F₈, C₅F₈, CH₃F, CH₂F₂, C₂HF₅, CHF₃, NF₃, SF₆, or the like, a second reaction gas containing oxygen, such as O₂, NO, NO₂, or the like, and a sputtering gas, such as He, Ne, Ar, Xe, or the like. In this case, the etching speed of the silicon nitride films 2040 to 2052 may vary depending on the silicon contents of the silicon nitride films 2040 to 2052.

According to an embodiment, the etching speed may be increased in a stepwise manner from the uppermost silicon nitride film 2052 toward the lowermost silicon nitride film 2040, so that each of the pixel openings 2312 may have a width that increases in a stepwise manner in a direction from the second surface 2304 of the membrane 2300 toward the first surface 2302 of the membrane 2300. As a result, each of the pixel openings 2312 of the membrane 2300 may have a lower width d3 greater than an upper width d4, as illustrated in FIG. 25. That is, the lower portions of the pixel openings 2312 penetrating the lowermost silicon nitride film 2340 may have the width d3 greater than the width d4 of the upper portions of the pixel openings 2312 penetrating the uppermost silicon nitride film 2352.

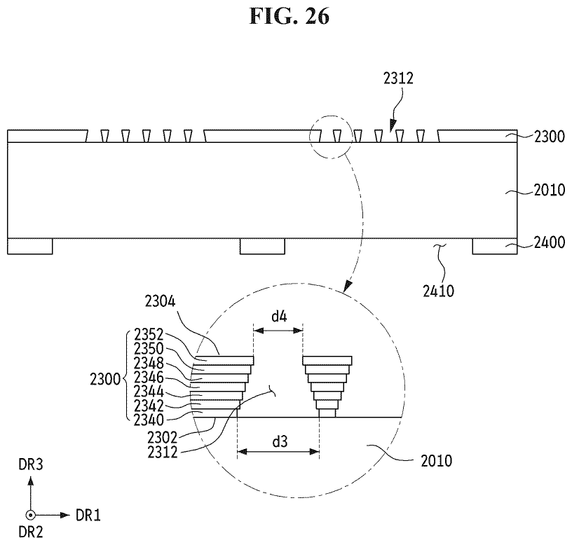

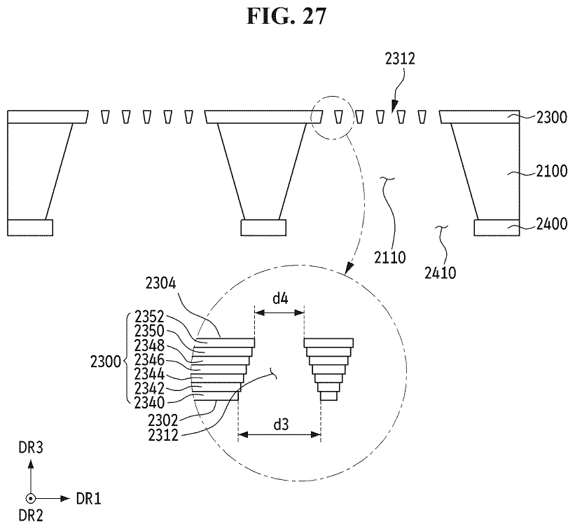

Referring to FIGS. 26 and 27, the mask substrate 2010 may be patterned to form the mask frame 2100 from the mask substrate 2010. Specifically, the mask substrate 2010 may be patterned to form the mask frame 2100 having the cell openings 2110 communicating with the pixel openings 2312. In an embodiment, for example, the rear inorganic film 2400 may be patterned to form the rear openings 2410 that expose rear portions of the mask substrate 2010, and an etching process using the rear inorganic film 2400 as an etching mask may be performed to form the cell openings 2110 that expose the pixel openings 2312. The rear openings 2410 may be formed through an RIE process, and the cell openings 2110 may be formed by a wet etching process using an etchant including (CH₃)₄NOH (TMAH) or potassium hydroxide (KOH). In such an embodiment, since the method of forming the rear openings 2410 and the cell openings 2110 is substantially the same as that described above with reference to FIGS. 22 and 23, any repetitive detailed description thereof will be omitted.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A deposition mask comprising:
a mask frame provided with a cell opening; and
a membrane disposed on the mask frame and provided with a plurality of pixel openings communicating with the cell opening,
wherein the membrane includes silicon nitride and has a first surface adjacent to the mask frame and a second surface spaced apart from the mask frame, and
a silicon content of the membrane increases in a direction from the first surface toward the second surface.

2. The deposition mask of claim 1, wherein an average value of the silicon content of the membrane is greater than a silicon content of stoichiometric silicon nitride.

3. The deposition mask of claim 1, wherein an average ratio of the silicon content to a nitrogen content of the membrane is in a range of about 0.8 to about 1.2.

4. The deposition mask of claim 1, wherein a minimum ratio of the silicon content to a nitrogen content of the membrane is about 0.8 or greater, and
a maximum ratio of the silicon content to the nitrogen content of the membrane is about 1.2 or less.

5. The deposition mask of claim 1, wherein a width of each of the pixel openings increases in a direction from the second surface toward the first surface.

6. The deposition mask of claim 5, wherein an inner surface of the membrane defining each of the pixel openings has an inclination angle of about 30°to about 85°.

7. The deposition mask of claim 1, wherein the membrane comprises a plurality of silicon nitride films stacked on the mask frame, and
silicon contents of the silicon nitride films increase in a stepwise manner in a direction from the first surface toward the second surface.

8. The deposition mask of claim 7, wherein among the silicon nitride films, a ratio of a silicon content to a nitrogen content of a silicon nitride film defining the first surface is about 0.8 or greater, and
among the silicon nitride films, a ratio of a silicon content to a nitrogen content of a silicon nitride film defining the second surface is about 1.2 or less.

9. The deposition mask of claim 7, wherein a width of each of the pixel openings increases in a stepwise manner in a direction from the second surface toward the first surface.

10. A method of manufacturing a deposition mask, the method comprising:
forming an inorganic film on a mask substrate;
patterning the inorganic film to form a membrane with a plurality of pixel openings exposing the mask substrate; and
patterning the mask substrate to form a mask frame with a cell opening communicating with the pixel openings,
wherein the inorganic film includes silicon nitride and has a first surface adjacent to the mask substrate and a second surface spaced apart from the mask substrate, and
a silicon content of the inorganic film increases in a direction from the first surface toward the second surface.

11. The method of claim 10, wherein an average value of the silicon content of the inorganic film is greater than a silicon content of stoichiometric silicon nitride.

12. The method of claim 10, wherein an average ratio of the silicon content to a nitrogen content of the inorganic film is in a range of about 0.8 to about 1.2.

13. The method of claim 10, wherein a minimum ratio of the silicon content to a nitrogen content of the inorganic film is about 0.8 or greater, and
a maximum ratio of the silicon content to the nitrogen content of the inorganic film is about 1.2 or less.

14. The method of claim 10, wherein the inorganic film is formed by a chemical vapor deposition process using a first source gas containing silicon and a second source gas containing nitrogen, and
a supply flow rate ratio of the first source gas to the second source gas is increased while forming the inorganic film.

15. The method of claim 10, wherein the pixel openings are formed by an anisotropic etching process using a reaction gas containing fluorine, and
each of the pixel openings is formed in a way such that a width thereof increases in a direction from the second surface toward the first surface.

16. The method of claim 15, wherein the pixel openings are formed in a way such that an inner surface of the membrane defining each of the pixel openings has an inclination angle of about 30° to about 85°.

17. The method of claim 10, wherein the inorganic film comprises a plurality of silicon nitride films stacked on the mask substrate, and
the silicon nitride films are formed in a way such that silicon contents thereof increase in a stepwise manner in a direction from the first surface toward the second surface.

18. The method of claim 17, wherein the silicon nitride films are formed by a chemical vapor deposition process using a first source gas containing silicon and a second source gas containing nitrogen, and
a supply flow rate ratio of the first source gas to the second source gas is increased in a stepwise manner while forming the silicon nitride films.

19. The method of claim 17, wherein among the silicon nitride films, a silicon nitride film defining the first surface is formed in a way such that a ratio of a silicon content to a nitrogen content thereof is about 0.8 or greater, and
among the silicon nitride films, a silicon nitride film defining the second surface is formed in a way such that a ratio of a silicon content to a nitrogen content thereof is about 1.2 or less.

20. An electronic device comprising a display panel,
wherein the display panel comprises a substrate and a plurality of light emitting layers formed on the substrate by using a deposition mask, and
the deposition mask comprises:
a mask frame provided with a cell opening; and
a membrane disposed on the mask frame and provided with a plurality of pixel openings communicating with the cell opening,
wherein the membrane includes silicon nitride and has a first surface adjacent to the mask frame and a second surface spaced apart from the mask frame, and
a silicon content of the membrane increases in a direction from the first surface toward the second surface.
